(19) United States
(12) Patent Application Publication
(10) Pub. No.: US 2025/0255016 A1
(43) Pub. Date: Aug. 7, 2025

(54) METHOD OF MANUFACTURING IMAGE SENSOR, IMAGE SENSOR, AND ELECTRONIC DEVICE INCLUDING THE IMAGE SENSOR

(71) Applicant: SAMSUNG ELECTRONICS CO., LTD., Suwon-si (KR)

(72) Inventors: Hyeonsoo Park, Suwon-si (KR); Byunghong Chung, Hwaseong-si (KR); Hongkyu Park, Suwon-si (KR); Sookyoung Roh, Suwon-si (KR); Sungmo Ahn, Suwon-si (KR); Choonlae Cho, Suwon-si (KR)

(73) Assignee: SAMSUNG ELECTRONICS CO., LTD., Suwon-si (KR)

(21) Appl. No.: 18/923,113

(22) Filed: Oct. 22, 2024

(30) Foreign Application Priority Data
Feb. 1, 2024 (KR) 10-2024-0016218

(51) Int. Cl. H01L 27/146

(52) U.S. Cl. CPC H10F 39/024; H10F 39/8023; H10F 39/805; H10F 39/806

(57) ABSTRACT

Provided is a method of manufacturing an image sensor, the method including forming a spacer layer on a sensor substrate that includes a first pixel configured to sense light of a first wavelength and a second pixel configured to sense light of a second wavelength, forming a dielectric layer on the spacer layer, forming an engraved pattern in the dielectric layer through patterning, and forming nanoposts included in a color separating lens layer by filling the engraved pattern formed in the dielectric layer with a nanostructure material.

### CROSS-REFERENCE TO RELATED APPLICATION

This application claims priority to Korean Patent Application No. 10-2024-0016218, filed on Feb. 1, 2024, in the Korean Intellectual Property Office, the disclosure of which is incorporated by reference herein in its entirety.

### BACKGROUND

### 1. Field

Example embodiments of the present disclosure relate to a method of manufacturing an image sensor including a nanostructure, an image sensor, and an electronic device including the image sensor.

### 2. Description of Related Art

An image sensor has a structure in which pixels are repeatedly arranged, and includes an optical structure that focuses light in a corresponding wavelength band on each pixel and an electrical structure that photoelectrically converts light incident on each pixel into an image signal. A quantum efficiency of converting light into electricity is one of important factors that determines optical quality of these image sensors, and an optical performance may be defined using spectral scale by wavelength for each pixel. However, a color filter generally applied to image sensors is suitable for more accurately expressing colors, but absorb or reflect light of other colors except for light of a corresponding color, which significantly reduces amount of light reaching photosensitive cells. In addition, in a low light environment with insufficient light, when an image sensor with relatively low quantum efficiency is used, image quality is further reduced due to noise unrelated to the amount of light, such as electrical background noise or shot noise. A development of image sensors continues to undergo structural changes to improve the optical performance thereof by reducing light loss.

### SUMMARY

One or more embodiments provide an image sensor including a nanostructure capable of improving light utilization efficiency by separating and concentrating incident light by wavelength without absorbing or blocking the incident light, thereby ensuring optical performance, and a method of manufacturing the image sensor.

One or more embodiments also provide a method of manufacturing an image sensor capable of implementing nanostructures of various sizes in accordance with a design to ensure optical performance.

One or more embodiments also provide an electronic device including an image sensor.

Additional aspects will be set forth in part in the description which follows and, in part, will be apparent from the description, or may be learned by practice of the embodiments of the disclosure.

According to an aspect of an example embodiment, there is provided a method of manufacturing an image sensor, the method including forming a spacer layer on a sensor substrate that includes a first pixel configured to sense light of a first wavelength and a second pixel configured to sense light of a second wavelength, forming a dielectric layer on the spacer layer, forming an engraved pattern in the dielectric layer through patterning, and forming nanoposts included in a color separating lens layer by filling the engraved pattern formed in the dielectric layer with a nanostructure material, wherein the forming of the engraved pattern in the dielectric layer includes forming a first engraved pattern to form a plurality of first nanoposts that includes a nanopost having a width that is less than or equal to an exposure diffraction limit, the plurality of first nanoposts having at least one or more widths, and forming a second engraved pattern to form a plurality of second nanoposts that includes a nanopost having a width that is greater than the exposure diffraction limit, wherein the forming of the first engraved pattern includes forming a first mask layer on the dielectric layer, forming a first opening at a position where the first engraved pattern is to be formed by patterning the first mask layer through the patterning including an exposure, forming a sidewall within the first opening by forming a step cover layer on the patterned first mask layer, etching the dielectric layer through the first opening, forming the first engraved pattern having a width less than a width of the first opening by a sidewall portion of the step cover layer left during an etching process, and removing the first mask layer.

The forming of the second engraved pattern may include forming a second mask layer on the dielectric layer, forming a second opening at a position where the second engraved pattern is to be formed by patterning the second mask layer, forming the second engraved pattern having a width corresponding to the second opening by etching the dielectric layer through the second opening, and removing the second mask layer.

The plurality of first nanoposts may be formed by forming of the first engraved pattern, and filling the first engraved pattern with the nanostructure material, and the plurality of second nanoposts may be formed by forming of the second engraved pattern, and filling the second engraved pattern with the nanostructure material.

The filling of the nanostructure material to form the plurality of first nanoposts may be performed after the removing of the first mask layer, and the filling of the nanostructure material to form the plurality of second nanoposts may be performed after the removing of the second mask layer.

The plurality of first nanoposts and the plurality of second nanoposts may be formed respectively by filling the first engraved pattern and the second engraved pattern with the nanostructure material simultaneously.

The step cover layer may be removed during the etching to form the first engraved pattern.

A refractive index of the nanostructure material may be greater than a refractive index of the dielectric layer.

The method may further include forming an etch stop layer on the spacer layer, wherein the dielectric layer is formed on the etch stop layer.

The method may further include forming a second etch stop layer on the color separating lens layer, and forming a second color separating lens layer on the color separating lens layer.

The second color separating lens layer may be formed simultaneously as forming of the color separating lens layer after the forming of a spacer layer on the sensor substrate.

According to another aspect of an example embodiment, there is provided an image sensor including a sensor substrate including a two-dimensional (2D) array of unit pixels that respectively include a first pixel configured to sense light of a first wavelength and a second pixel configured to sense light of a second wavelength, a transparent spacer layer on the sensor substrate, and a color separating lens layer on the spacer layer, wherein the color separating lens layer, in a region corresponding to at least one pixel of the unit pixels, includes: first nanoposts including a nanopost having a width that is less than or equal to an exposure diffraction limit, the first nanoposts having at least one or more widths, and second nanoposts including a nanopost having a width greater than the exposure diffraction limit.

The image sensor may further include a second color separating lens layer on the color separating lens layer, wherein the second color separating lens layer, in a region corresponding to at least one pixel of the unit pixels, may include third nanoposts including a nanopost having a width that is less than or equal to the exposure diffraction limit, the third nanoposts having at least one or more widths, and fourth nanoposts including a nanopost having a width greater than the exposure diffraction limit.

The sensor substrate may include a first green pixel, a blue pixel, a red pixel, and a second green pixel in a Bayer pattern arrangement, wherein, when width sizes of the second nanoposts in a first green pixel corresponding region and a second green pixel corresponding region corresponding to the first green pixel and the second green pixel, a blue pixel corresponding region corresponding to the blue pixel, and a red pixel corresponding region corresponding to the red pixel of the color separating lens layer are Pa, Pb, and Pc, respectively, the width sizes of the second nanoposts in the first green pixel corresponding region and the second green pixel corresponding region, the blue pixel corresponding region, and the red pixel corresponding region may be in an order of Pb>Pc>Pa.

One second nanopost may be in the blue pixel corresponding region, four second nanoposts may be symmetrically at positions spaced apart from a center in the red pixel corresponding region, and four second nanoposts may be at positions spaced apart from the center and symmetrically in the first green pixel corresponding region and the second green pixel corresponding region.

A width of at least one of first nanoposts in the blue pixel corresponding region may be less than a width of each of first nanoposts in the first green pixel corresponding region, the second green pixel corresponding region, and the red pixel corresponding region.

According to still another aspect of an example embodiment, there is provided an electronic device including an image sensor configured to convert an optical image into an electrical signal, and a processor configured to control an operation of the image sensor and store and output the electrical signal generated by the image sensor, wherein the image sensor includes a sensor substrate having a two-dimensional (2D) array of unit pixels respectively including a first pixel configured to sense light of a first wavelength and a second pixel configured to sense light of a second wavelength, a transparent spacer layer on the sensor substrate, and a color separating lens layer on the spacer layer, wherein the color separating lens layer, in a region corresponding to at least one pixel of the unit pixels, includes first nanoposts including a nanopost having a width that is less than or equal to an exposure diffraction limit, the first nanoposts having at least one or more widths, and second nanoposts including a nanopost having a width greater than the exposure diffraction limit.

The image sensor may further include a second color separating lens layer on the color separating lens layer, wherein the second color separating lens layer, in a region corresponding to at least one pixel of the unit pixels, may include third nanoposts including a nanopost having a width that is less than or equal to the exposure diffraction limit, the third nanoposts having at least one or more widths, and fourth nanoposts including a nanopost having a width greater than the exposure diffraction limit.

The sensor substrate may include a first green pixel, a blue pixel, a red pixel, and a second green pixel in a Bayer pattern arrangement, and when width sizes of the second nanoposts in a first green pixel corresponding region and a second green pixel corresponding region corresponding to the first green pixel and the second green pixel, a blue pixel corresponding region corresponding to the blue pixel, and a red pixel corresponding region corresponding to the red pixel of the color separating lens layer are Pa, Pb, and Pc, respectively, the width sizes of the second nanoposts in the first green pixel corresponding region and the second green pixel corresponding region, the blue pixel corresponding region, and the red pixel corresponding region may be in an order of Pb>Pc>Pa.

One second nanopost may be in the blue pixel corresponding region, four second nanoposts may be symmetrically at positions spaced apart from a center in the red pixel corresponding region, and four second nanoposts may be disposed at positions spaced apart from the center and symmetrically in the first green pixel corresponding region and the second green pixel corresponding region.

A width of at least one of first nanoposts in the blue pixel corresponding region may be less than a width of each of first nanoposts in the first green pixel corresponding region, the second green pixel corresponding region, and the red pixel corresponding region.

### BRIEF DESCRIPTION OF THE DRAWINGS

The above and other aspects, features, and advantages of example embodiments of the disclosure will be more apparent from the following description taken in conjunction with the accompanying drawings, in which:

FIG. 1 is a schematic block diagram of an image sensor according to an example embodiment;

FIGS. 2A, 2B, and 2C are diagrams showing various arrangements in a pixel array of an image sensor;

FIGS. 3A and 3B are conceptual diagrams illustrating a structure and an operation of a color separating lens array;

FIGS. 4A and 4B are schematic different cross-sectional views of a pixel array of an image sensor according to an example embodiment;

FIG. 5A is a plan view schematically illustrating an arrangement of pixels in a pixel array;

FIG. 5B is a plan view exemplarily illustrating a plurality of nanoposts arranged in a region corresponding to a unit pixel of a color separating lens array of an image sensor according to an example embodiment;

FIG. 6A shows phase profiles of green light and blue light passing through a color separating lens array along line A-A′ of FIG. 5B;

FIG. 6B shows a phase of green light passing through the color separating lens array at centers of pixel corresponding regions;

FIG. 6C shows a phase of blue light passing through the color separating lens array at centers of pixel corresponding regions; FIG. 6D exemplarily illustrates a proceeding direction of green light incident on a first green light concentration region;

FIG. 6E exemplarily illustrates an array of a first green light concentration region; FIG. 6F exemplarily illustrates a proceeding direction of blue light incident on a blue light concentration region; FIG. 6G exemplarily illustrates an array of a blue light concentration region;

FIG. 7A shows phase profiles of green light and red light passing through the color separating lens array along line B-B′ in FIG. 5B;

FIG. 7B shows a phase of red light passing through the color separating lens array at the center of the pixel corresponding regions;

FIG. 7C shows a phase of green light passing through the color separating lens array at the center of the pixel corresponding regions;

FIG. 7D exemplarily illustrates a proceeding direction of red light incident on a red light concentration region;

FIG. 7E exemplarily illustrates an array of a red light concentration region;

FIG. 7F exemplarily illustrates a proceeding direction of green light incident on a green light concentration region;

FIG. 7G exemplarily illustrates an array of a green light concentration region;

FIGS. 8A and 8B are schematic different cross-sectional views of a pixel array of an image sensor according to another example embodiment;

FIGS. 9A, 9B, 90, and 9D are diagrams for explaining a method of manufacturing a pixel array of an image sensor according to an embodiment of FIGS. 4A and 4B;

FIGS. 10A, 10B, 10C, 10D, 10E, 10F, 10G, 10H, 10I, and 10J show manufacturing processes for forming nanoposts through a double patterning process according to a method of manufacturing an image sensor according to an example embodiment;

FIGS. 11A, 11B, 11C, 11D, 11E, 11F, 11G, 11H, 11I, 11J, and 11K show manufacturing processes for forming nanoposts through a double patterning process according to a method of manufacturing an image sensor according to an example embodiment;

FIGS. 12A, 12B, 12C, 12D, 12E, 12F, 12G, 12H, and 12I are diagrams for explaining a method of manufacturing pixel array of the image sensor according to an embodiment of FIGS. 8A and 8B;

FIG. 13 illustrates an example of a mask layer method of manufacturing an image sensor according to an embodiment;

FIGS. 14A, 14B, 14C, and 14D exemplarily illustrates various operations of forming a step cover layer according to a method of manufacturing an image sensor according to an example embodiment;

FIG. 15 is a block diagram of an example of an electronic device including an image sensor, according to an embodiment;

FIG. 16 is a block diagram illustrating a camera module of FIG. 15;

FIG. 17 is a block diagram of an electronic device including a multi-camera module; and

FIG. 18 is a detailed block diagram of a multi-camera module in the electronic device of FIG. 17.

### DETAILED DESCRIPTION

Reference will now be made in detail to embodiments, examples of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a method of manufacturing an image sensor, the image sensor, and an electronic device including the image sensor will be described in detail with reference to accompanying drawings. In the drawings, like reference numerals denote like components, and sizes of components in the drawings may be exaggerated for convenience of explanation. The embodiments of the disclosure are capable of various modifications and may be embodied in many different forms.

When a layer, a film, a region, or a panel is referred to as being “on” another element, it may be directly on/under/at left/right sides of the other layer or substrate, or intervening layers may also be present. An expression used in the singular encompasses the expression of the plural, unless it has a clearly different meaning in the context. It will be further understood that when a portion is referred to as “comprising” another component, the portion may not exclude another component but may further comprise another component unless the context states otherwise.

The term “the” and the similar indicative terms may be used in both the singular and the plural. If there is no explicit description of the order of steps constituting a method or no contrary description thereto, these steps may be performed in an appropriate order, and are not limited to the order described.

In addition, the terms “ . . . unit”, “module”, etc. described herein mean a unit that processes at least one function or operation, may be implemented as hardware or software, or may be implemented as a combination of hardware and software.

Connections of lines or connection members between elements shown in the drawings are illustrative of functional connections and/or physical or circuitry connections, and may be redisposed in an actual device, or may be represented as additional various functional connections, physical connections, or circuitry connections.

The use of all examples or example terms is merely for describing the technical concept in detail, and the scope thereof is not limited by these examples or example terms unless limited by claims.

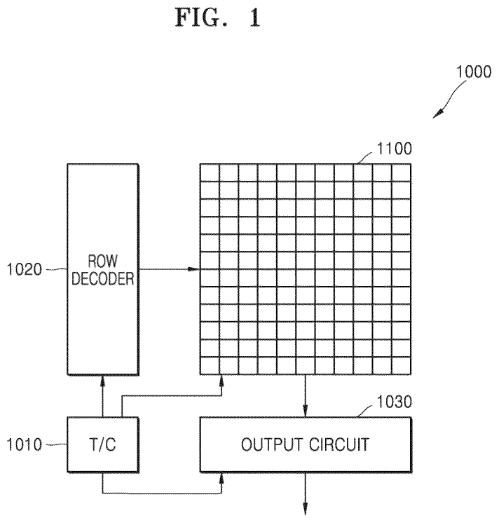

FIG. 1 is a schematic block diagram of an image sensor 1000 according to an embodiment.

Referring to FIG. 1, the image sensor 1000 may include a pixel array 1100, a timing controller 1010, a row decoder 1020, and an output circuit 1030. The image sensor 1000 may be, for example, a charge-coupled device (CCD) image sensor or a complementary metal oxide semiconductor (CMOS) image sensor.

The pixel array 1100 may include pixels that are two-dimensionally arranged in a plurality of rows and columns. The row decoder 1020 may select one of the rows of the pixel array 1100 in response to a row address signal output from the timing controller 1010. The output circuit 1030 may output a light sensing signal, in a column unit, from a plurality of pixels arranged along the selected row. To this end, the output circuit 1030 may include a column decoder and an analog-to-digital converter (ADC). For example, the output circuit 1030 may include a plurality of ADCs that are disposed respectively in columns between the column decoder and the pixel array 1100 or may include one ADC disposed at an output end of the column decoder. The timing controller 1010, the row decoder 1020, and the output circuit 1030 may be implemented as a single chip or in separate chips. A processor for processing an image signal output from the output circuit 1030 may be implemented as a single chip together with the timing controller 1010, the row decoder 1020, and the output circuit 1030.

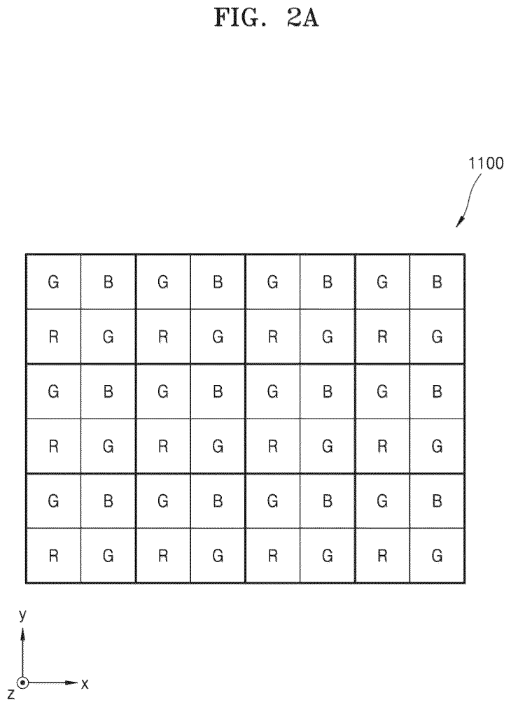

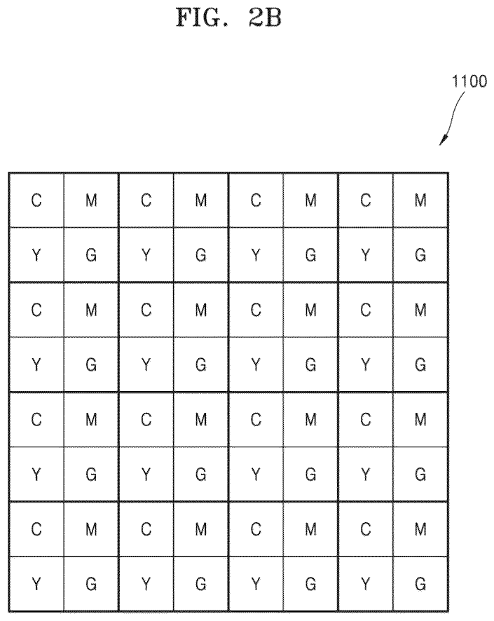

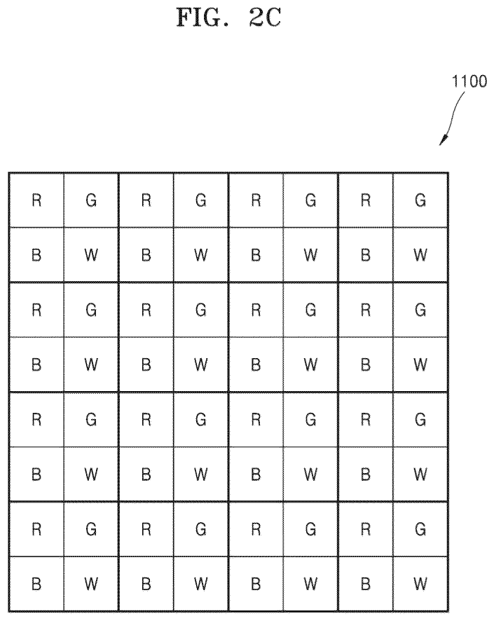

The pixel array 1100 may include a plurality of pixels configured to sense light of different wavelengths. The pixel arrangement may be implemented in various ways. For example, FIGS. 2A, 2B, and 2C illustrate various arrangements in the pixel array 1100 of the image sensor 1000.

First, FIG. 2A illustrates an example in which the pixel array 1100 of the image sensor 1000 includes a Bayer pattern. Referring to FIG. 2A, one unit pixel may include four quadrant regions, and first to fourth quadrant regions may be respectively a blue pixel B, a green pixel G, a red pixel R, and a green pixel G. Such unit pixel may be repeatedly arranged in a two-dimension manner in a first direction (X direction) and a second direction (Y direction). For example, in a unit pixel of a 2×2 array, two green pixels G may be disposed in one diagonal direction, and one blue pixel B and one red pixel R may be disposed in other diagonal direction. With respect to the overall pixel arrangement, a first row in which a plurality of green pixels G and a plurality of blue pixels B are alternately arranged in the first direction, and a second row in which a plurality of red pixels R and the plurality of green pixels G are alternately arranged in the first direction may be repeatedly arranged in the second direction.

However, an arrangement of the pixel array 1100 is not limited to the Bayer pattern, and various arrangements other than the Bayer pattern may be employed. For example, as shown in FIG. 2B, the pixel array 1100 may be arranged in a CYGM manner in which a magenta pixel M, a cyan pixel C, a yellow pixel Y, and a green pixel G are included in and constitute a unit pixel. In addition, as illustrated in FIG. 2C, the pixel array 1100 also may be arranged in a RGBW manner in which the green pixel G, the red pixel R, the blue pixel B, and a white pixel W are included in and constitute a unit pixel. In addition, a unit pixel may have a 3×2 array form. However, embodiments are not limited thereto, and pixels of the pixel array 1100 may be arranged in various ways according to color characteristics of the image sensor 1000. Hereinafter, for a sake of convenience, example embodiments are described by taking an example in which the pixel array 1100 of the image sensor 1000 has the Bayer pattern, but principles of embodiments described below may be also applied to other types of pixel arrays other than the Bayer pattern.

The pixel array 1100 of the image sensor 1000 may include a color separating lens array configured to collect light of a certain color corresponding to a certain pixel.

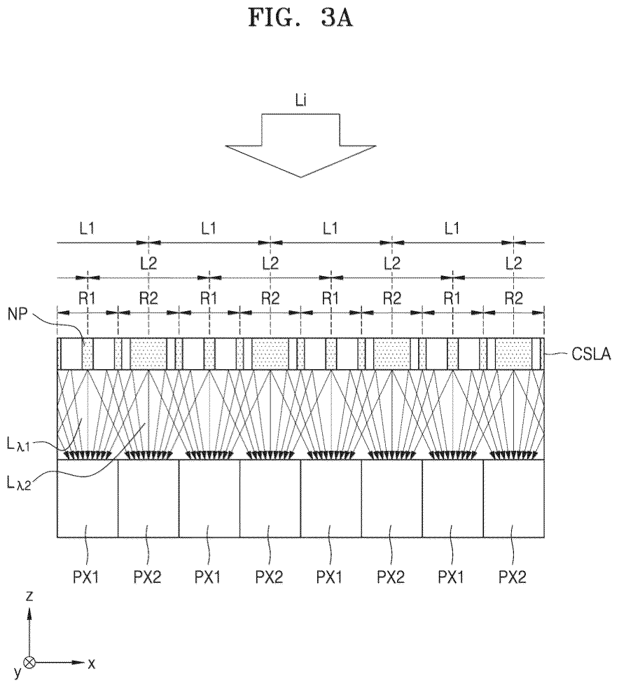

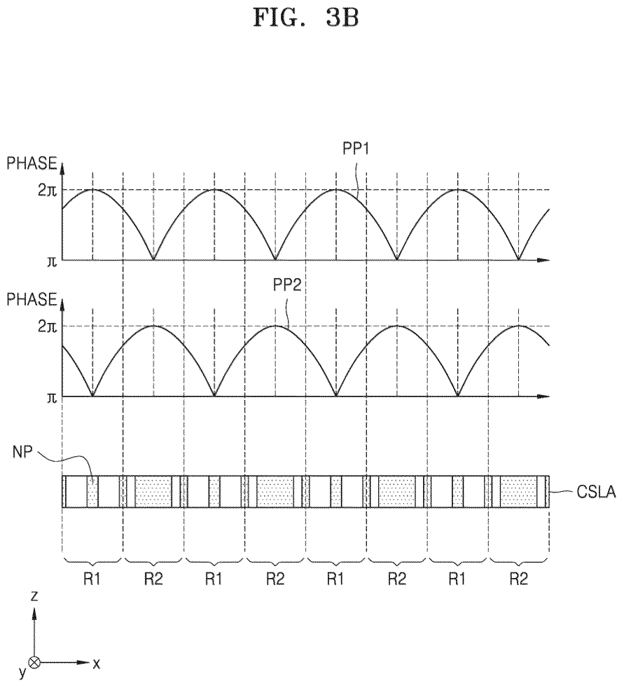

FIGS. 3A and 3B are conceptual diagrams illustrating a structure and an operation of a color separating lens array CSLA.

Referring to FIG. 3A, the color separating lens array CSLA may include nanostructures that differently changes a phase of incident light Li according to a wavelength, for example, a plurality of nanoposts NP. The color separating lens array CSLA may be partitioned in a variety of ways. For example, the color separating lens array CSLA may be partitioned into a first pixel corresponding region R1 corresponding to a first pixel PX1, on which a first wavelength light L_{λ1} included in the incident light Li is collected, and a second pixel corresponding region R2 corresponding to a second pixel PX2, on which a second wavelength light L_{λ2} included in the incident light Li is collected. The first pixel corresponding region R1 and the second pixel corresponding regions R1 and R2 may respectively include the one or more nanoposts NP and be disposed to face the first pixel PX1 and the second pixel PX2, respectively. As another example, the color separating lens array CSLA may be partitioned into a first wavelength concentration region L1 that collects the first wavelength light L_{λ1} on the first pixel PX1, and a second wavelength concentration region L2 that collects the second wavelength light L_{λ2} on the second pixel PX2. The first wavelength concentration region L1 and the second wavelength concentration region L2 may partially overlap.

The color separating lens array CSLA may concentrate the first wavelength light L_{λ1} on the first pixel PX1, and the second wavelength light L_{λ2} to the second pixel PX2 by forming different phase profiles in the first wavelength light L_{λ1} and the second wavelength light L_{λ2} included in the incident light Li.

For example, referring to FIG. 3B, at a position right after light passes through the color separating lens array CSLA, e.g., at a position of the bottom surface of the color separating lens array CSLA, the first wavelength light L_{λ1} may have a first phase profile PP1, and the second wavelength light L_{λ2} may have a second phase profile PP2, which allows the first wavelength light L_{λ1} and the second wavelength light L_{λ2} to be collected on the corresponding first and second pixels PX1 and PX2, respectively, by the color separating lens array CSLA. For example, the first wavelength light L_{λ1} passing through the color separating lens array CSLA may have the first phase profile PP1 which is greatest in a certain portion of the first pixel corresponding region R1 and is reduced in a direction away and spaced apart from the certain portion, that is, in a direction of the second pixel corresponding region R2. Such phase profile may be similar to a phase profile of light converging through a lens and the first wavelength light L_{λ1} may be focused on the first pixel PX1. In addition, the second wavelength light L_{λ2} passing through the color separating lens array CSLA may have the second phase profile PP2 which is greatest in a certain portion of the second pixel corresponding region R2 and is reduced in a direction away and spaced apart from the certain portion, that is, a direction of the first pixel corresponding region R1, so that the second wavelength light L_{λ2} may be focused on the second pixel PX2. FIG. 3B illustrates that the first phase profile PP1 of the first wavelength light L_{λ1} that passed through the color separating lens array CSLA and the second phase profile PP2 of the second wavelength light L_{λ2} that passed through the color separating lens array CSLA respectively have greatest peak at the centers of the first pixel corresponding region R1 and the second pixel corresponding region R2, however, the first phase profile PP1 and the second phase profile PP2 are not limited thereto. For example, the nanopost NP of the color separating lens array CSLA may be arranged according to a certain rule such that peak parts of the first phase profile PP1 and the second phase profile PP2 each have a complex phase profile with a plurality of peaks. Here, the rule may be applied to parameters of the nanoposts NP such as a shape, size (width and height), interval, and arrangement type, etc., and these parameters may be determined according to a phase profile to be implemented through the color separating lens array CSLA.

A refractive index of a material may be different depending on a wavelength of reacting light, and thus, the color separating lens array CSLA may provide different phase profiles with respect to the first wavelength light L_{λ1} and the second wavelength light L_{λ2}, as illustrated in FIG. 3B. For example, even for the same material, a refractive index is different depending on a wavelength of light reacting with a material, and a phase delay experienced by the light when passing through the material also may be different depending on the wavelength, and thus, a different phase profiles may be formed for each wavelength. For example, a refractive index of the first pixel corresponding region R1 with respect to the first wavelength light L_{λ1} may be different from a refractive index of the first pixel corresponding region R1 with respect to the second wavelength light L_{λ2}, and a phase delay experienced by the first wavelength light L_{λ1} passing through the first pixel corresponding region R1 may be different from a phase delay experienced by the second wavelength light L_{λ2} passing through the first pixel corresponding region R1, and thus, when the color separating lens array CSLA is formed considering such characteristics of light, the color separating lens array CSLA may provide different phase profiles with respect to the first wavelength light L_{λ1} and the second wavelength light L_{λ2}.

The color separating lens array CSLA may include nanoposts NP arranged in a certain rule so that the first wavelength light L_{λ1} and the second wavelength light L_{λ2} have the first phase profile PP1 and the second phase profile PP2, respectively. Here, the rule may be applied to parameters of the nanopost NP, such as a shape, size (width and height), interval, and arrangement type, etc., and these parameters may be determined according to a phase profile to be implemented through the color separating lens array CSLA.

A rule applied to arrangement of the nanoposts NP in the first pixel corresponding region R1 and a rule applied to arrangement of the nanoposts NP in the second pixel corresponding region R2 may be different from each other. For example, a size, shape, interval, and/or arrangement of the nanoposts NP provided in the first pixel corresponding region R1 may be different from a size, shape, distance, and/or arrangement of the nanoposts NP provided in the second pixel corresponding region R2.

The diameter of cross-section of the nanopost NP may have a dimension of a sub-wavelength. Here, the sub-wavelength refers to a wavelength less than a wavelength band of incident light subject to separation. For example, the nanopost NP may have a less dimension than a shorter wavelength among a first wavelength and a second wavelength. When the incident light Li is visible light, the cross-sectional diameter of the nanopost NP may have a dimension less than, for example, about 400 nm, about 300 nm, or about 200 nm. A height of the nanopost NP may be, for example, about 500 nm to about 1500 nm, and may be greater than the cross-sectional diameter. The nanopost NP may be a combination of two or more posts stacked in a height direction (Z direction).

The nanopost NP may include a material with a higher refractive index than a peripheral material. For example, the nanopost NP may include c-Si, p-Si, a-Si and a Group III-V compound semiconductor (gallium phosphide (GaP), gallium nitride (GaN), gallium arsenide (GaAs), etc.), silicon carbide (SiC), titanium oxide (TiO₂), silicon nitride (SiN), and/or a combination thereof. The nanopost NP having a different refractive index from a peripheral material may change a phase of light passing through the nanopost NP. This is caused by a phase delay that occurs due to a shape dimension of a sub-wavelength of the nanopost NP, and a degree at which a phase is delayed may be determined by a detailed shape dimension, arrangement, etc. of the nanopost NP. The peripheral material of the nanopost NP may include a dielectric material with a lower refractive index than the nanopost NP. For example, the peripheral material may include silicon oxide (SiO₂) or air.

The first wavelength light L_{λ1} and the second wavelength light L_{λ2} may be in infrared and visible light wavelength bands, but are not limited thereto and may operate at various wavelengths according to an arrangement rule of an array of the plurality of nanoposts NP. In addition, although an example in which an incident light is separated by two wavelengths for concentration is illustrated, but incident light may be separated in three or more directions according to a wavelength for concentration.

In addition, even though some embodiments describe that the color separating lens array CSLA has a single layer structure, but the color separating lens array CSLA may have a structure in which a plurality of layers are stacked. In addition, for example, the color separating lens array CSLA may be formed that a first layer concentrates visible light on a particular pixel, and a second layer concentrates infrared light on another pixel.

Hereinafter, an example in which the color separating lens array CSLA is applied to the pixel array 1100 of the image sensor 1000 will be described in more detail.

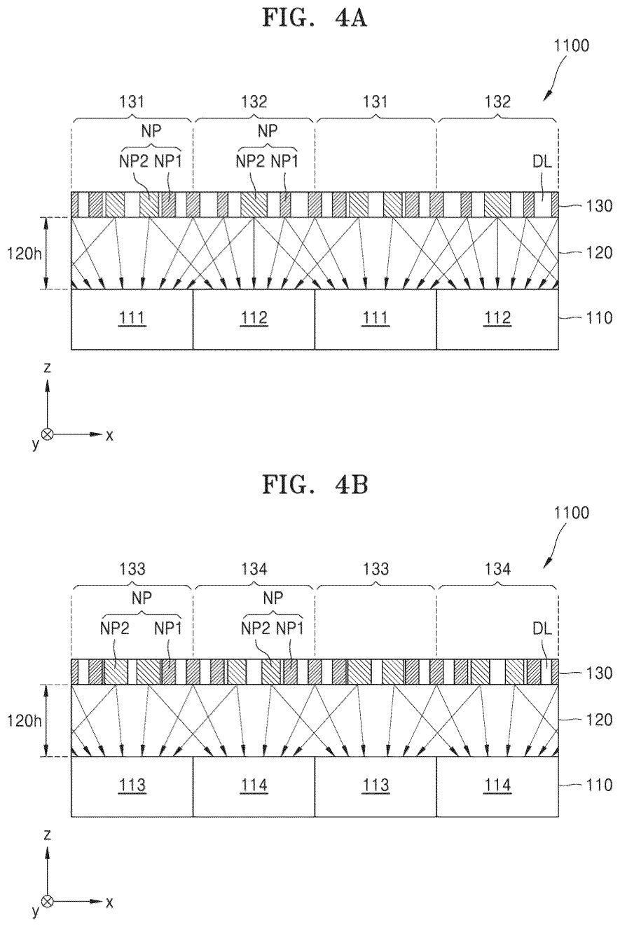

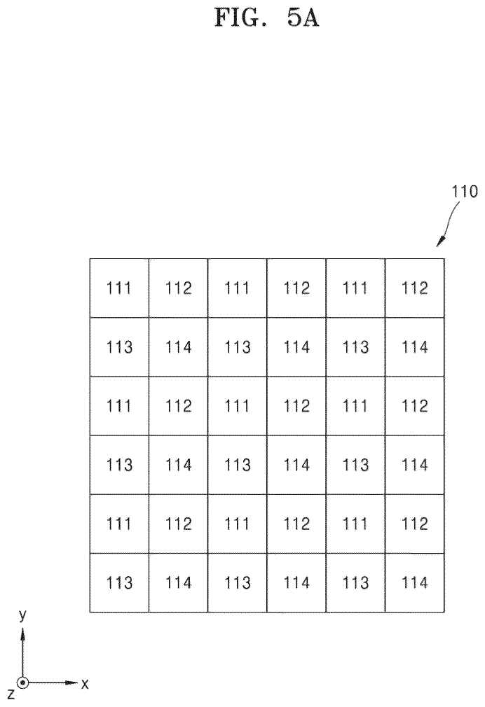

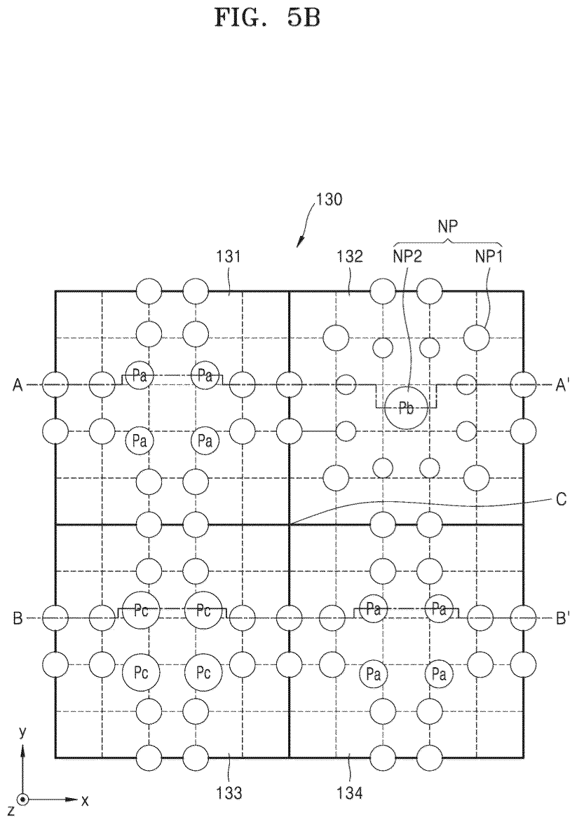

FIGS. 4A and 4B are schematic different cross-sectional views of the pixel array 1100 of the image sensor 1000 according to an example embodiment. FIG. 5A is a plan view schematically illustrating an arrangement of pixels in the pixel array 1100. FIG. 5B is a plan view exemplarily illustrating the plurality of nanoposts NP arranged in a region corresponding to a unit pixel of a color separating lens array 130.

Referring to FIGS. 4A and 4B, the pixel array 1100 of the image sensor 1000 includes a sensor substrate 110 including a plurality of pixels 111, 112, 113, and 114 for sensing light, a transparent spacer layer 120 disposed on the sensor substrate 110, and the color separating lens array 130 disposed on the spacer layer 120.

The sensor substrate 110 includes a plurality of first pixels that sense light of a first wavelength and a plurality of second pixels that sense light of a second wavelength different from the first wavelength, and has a two-dimensional (2D) arrangement of unit pixels including the first pixel and the second pixel. The sensor substrate 110 includes a repeated arrangement of the first pixels and the second pixels in a first direction and a repeated arrangement of the first pixels and the second pixels in a second direction perpendicular to the first direction, and an unit pixel may include four pixels arranged in a 2×2 arrangement. In addition, the color separating lens array 130 is provided to change a phase of the light of the first wavelength and concentrate the light of the first wavelength on each first pixel, and change a phase of the light of the second wavelength and concentrate the light of the second wavelength on each second pixel.

For example, when the pixel array 1100 of the image sensor 1000 in FIGS. 4A and 4B includes a pixel arrangement of the Bayer pattern as shown in FIG. 2A, the sensor substrate 110 may include a first green pixel 111, a blue pixel 112, a red pixel 113, and a second green pixel 114 that each convert received light into an electrical signal. As shown in FIG. 4A, the first green pixel 111 and the blue pixel 112 may be alternately arranged in the first direction (X direction), and on a cross-section where positions in the Y direction are different, as shown in FIG. 4B, the red pixel 113 and the second green pixel 114 may be alternately arranged.

FIG. 5A shows an arrangement of photosensitive cells of the sensor substrate 110 when the pixel array 1100 of the image sensor 1000 has the Bayer pattern arrangement as shown in FIG. 2A.

Referring to FIG. 5A, in the Bayer pattern arrangement, the unit pixel of the sensor substrate 110 may include the first green pixel 111, the second green pixel 114, the blue pixel 112, and the red pixel 113, and the pixel array 1100 may include a 2D array in which these unit pixels are repeated. The first green pixel 111 and the second green pixel 114 may sense green light, the blue pixel 112 may sense blue light, and the red pixel 113 may sense red light. A separator for cell separation may be further formed at a boundary between cells.

Referring again to FIGS. 4A and 4B, the spacer layer 120 is disposed between the sensor substrate 110 and the color separating lens array 130 to maintain a constant distance between the sensor substrate 110 and the color separating lens array 130. The spacer layer 120 may include a material that is transparent in visible light, for example, a dielectric material that has a lower refractive index than the nanoposts NP and has a lower absorption rate in a visible light band, such as SiO₂, siloxane-based spin on glass (SOG), etc. A thickness h of the spacer layer 120 may be selected within the range of hₜ−p≤h≤hₜ+p. Here, a theoretical thickness hₜ of the spacer layer 120 may be expressed by [Equation 1] below, assuming that a refractive index of the spacer layer 120 with respect to a wavelength of λ₀ is n and a pitch of a pixel is p.

$${h}_{t} = \frac{{np}^{2}}{{λ}_{0}} - \frac{{λ}_{0}}{4 n} \qquad [ Equation 1 ]$$

The theoretical thickness hₜ of the spacer layer 120 may mean a focal distance at which light with the wavelength of λ₀ is focused on an upper surface of pixels 111, 112, 113, and 114 by the color separating lens array 130. λ₀ may denote the wavelength that is a reference for determining the thickness h of the spacer 120. For example, the thickness h of the spacer layer 120 may be formed with respect to 540 nm that is a central wavelength of green light.

The color separating lens array 130 may be supported by the spacer layer 120, and nanostructures, such as the nanoposts NP, may be formed. For example, the color separating lens array 130 may form a color separating lens layer and may include nanoposts NP, which are high refractive materials, and a dielectric layer DL, which is a low refractive material between the nanoposts NP. For example, the nanopost NP may include c-Si, p-Si, a-Si and a Group III-V compound semiconductor (GaP, GaN, GaAs etc.), SiC, TiO₂, SiN, and/or a combination thereof. The dielectric layer DL may include a dielectric material with a lower refractive index than the material of the nanopost NP, for example, air or SiO₂.

FIG. 5B shows an example of an arrangement of the nanoposts NP included in pixel corresponding regions 131, 132, 133, and 134 included in the unit pixel of the color separating lens array 130.

Referring to FIG. 5B, the color separating lens array 130 may be partitioned into four pixel corresponding regions 131, 132, 133, and 134 respectively corresponding to and facing pixels 111, 112, 113, and 114 of FIG. 5A. A first green pixel corresponding region 131 may correspond to and face a first green pixel 111 and be disposed on the first green pixel 111, a blue pixel corresponding region 132 may correspond to and face a blue pixel 112 and be disposed on the blue pixel 112, a red pixel corresponding region 133 may correspond to and face a red pixel 113 and be disposed on the red pixel 113, and a second green pixel corresponding region 134 may correspond to and face a second green pixel 114 and be disposed on the second green pixel 114. For example, the pixel corresponding regions 131, 132, 133, and 134 of the color separating lens array 130 may be arranged to respectively face each of pixels 111, 112, 113, and 114 of the sensor substrate 110. The pixel corresponding regions 131, 132, 133, and 134 may be 2D arranged in the first direction (X direction) and the second direction (Y direction) such that first rows in which the first green pixel corresponding regions 131 and the blue pixel corresponding regions 132 are alternately arranged, and second rows in which the red pixel corresponding regions 133 and the second green pixel corresponding regions 134 are alternately arranged and repeatedly alternate each other. The color separating lens array 130 may also include a plurality of 2D arranged unit patterns like a pixel arrangement of the photosensitive cells of the sensor substrate 110, and each unit pattern may include the pixel corresponding regions 131, 132, 133, and 134 that are arranged in a 2×2 array.

The pixel corresponding regions 131, 132, 133, and 134 of the color separating lens array 130 may include the nanoposts NP having size, shape, interval, and/or arrangement determined such that green light is separated and concentrated on the first and second green pixels 111 and 114, blue light is separated and concentrated on the blue pixel 112, and red light is separated and concentrated on the red pixel 113. A thickness of the color separating lens array 130 in a third direction (Z direction) may be similar to a height of the nanopost NP, and for example, may be about 500 nm to about 1500 nm.

As exemplarily illustrated in FIGS. 4A, 4B, and 5B, the color separating lens array 130 may include, for example, cylindrical nanoposts NP each having a circular cross-section, for example, first nanoposts NP1 and second nanoposts NP2, in the pixel corresponding regions 131, 132, 133, and 134.

The first nanopost NP1 may represent a nanopost with a relatively small width that may be obtained through first patterning, and may be a nanopost with a width close to an exposure diffraction limit, or a width of the exposure diffraction limit or less. As described above, the first nanopost NP1 corresponds to a nanopost in a size range that at least partially requires consideration of the influence of the exposure diffraction limit during a manufacturing process, and at least one of the first nanoposts NP1 formed in the pixel corresponding regions 131, 132, 133, and 134 may have a width of the exposure diffraction limit or less. The second nanopost NP2 may represent a nanopost having a relatively great width that may be obtained through second patterning, and may have a width, for example, greater than the exposure diffraction limit. As described above, the second nanopost NP2 corresponds to a nanopost in a size range that at least partially does not need to consider the influence of the exposure diffraction limit during a manufacturing process, and the second nanoposts NP2 formed in the pixel corresponding regions 131, 132, 133, and 134 may each have a width greater than the exposure diffraction limit.

As described above, at least one of the first nanoposts NP1 formed in the pixel corresponding regions 131, 132, 133, and 134 may have a width of the exposure diffraction limit or less, and the second nanoposts NP2 formed in the pixel corresponding regions 131, 132, 133, and 134 may each have a width greater than the exposure diffraction limit.

The exposure diffraction limit may indicate the minimum size (corresponding to a width or a diameter) of a pattern that may be formed in a mask layer by optical imaging during an exposure process. The pattern is formed as an opening in the mask layer, and the exposure diffraction limit may be expressed as, for example, D=λ/(2NA). Here, D may correspond to the minimum size (width or diameter) of the pattern (opening) that may be formed by patterning the mask layer by optical imaging during the exposure process. A corresponds to a wavelength of light used in the exposure process, and NA corresponds to a numerical aperture of an imaging optical system. As described above, the minimum size of the pattern formed by the exposure process may be restricted by the exposure diffraction limit.

As will be described below, in order to manufacture the color separating lens array 130 including the first nanoposts NP1 and the second nanoposts NP2, the mask layer including a photoresist material, etc. formed on a dielectric layer is firstly patterned to form the first nanopost NP1 and secondly patterned to form the second nanopost NP2 through an exposure process or an exposure process and a subsequent etching process. As described above, through the patterning process, the mask layer may be firstly patterned to form the first nanopost NP1 and secondly patterned to form the second nanopost NP2. The first nanopost NP1 and the second nanopost NP2A may be formed by etching the dielectric layer through the pattern (opening) of the mask layer formed by patterning to form holes, and filling the holes with a nanostructure material.

According to the image sensor 1000 and a method of manufacturing the image sensor 1000 according to the example embodiment, the color separating lens array 130 including the first nanoposts NP1 and the second nanoposts NP2 may be formed by applying a first patterning process for forming the first nanopost NP1 including nanoposts in a size range that requires consideration of the influence of the exposure diffraction limit, and a second patterning process for forming the second nanopost NP2 including nanoposts in a size range that does not need to consider the influence of the exposure diffraction limit. As described below, during the first patterning process, a step cover layer is stacked on the pattern (opening) of the mask layer to form a sidewall of the step cover layer in the opening, as a sidewall portion of the step cover layer withstand etching of the dielectric layer to be left, and the cross-sectional size of a final structure formed on the dielectric layer may be reduced compared to the pattern (opening) size of the mask layer by the sidewall portion of the step cover left during an etching process.

According to the image sensor 1000 and the method of manufacturing the image sensor 1000 according to the example embodiment, it is advantageous to implement patterning below the diffraction limit guaranteed in the exposure process, which improves design freedom and reduces the burden of the exposure process, and thus, dispersion may be improved by increasing the depth of focus, and pattern noise within a pixel or between adjacent pixels, such as color distortion of the image sensor 1000 or a difference between the green pixel Gr adjacent to the red pixel and the green pixel Gb adjacent to the blue pixel, may be suppressed.

In FIG. 5B, the second nanoposts NP2 are indicated by Pa, Pb, and Pc. As described above, the nanoposts Pa, Pb, and Pc may correspond to the second nanoposts NP2, and the unmarked nanoposts may correspond to the first nanoposts NP1, but are not limited thereto. For example, among the unmarked nanoposts, at least one nanopost with a relatively large width may correspond to the second nanopost NP2. Hereinafter, an example in which unmarked nanoposts correspond to the first nanoposts NP1 and the nanoposts Pa, Pb, and Pc correspond to the second nanoposts NP2 will be described.

When the nanoposts NP, for example, the first nanoposts NP1 and the second nanoposts NP2, each have a circular cross-section, the width of the nanopost NP may correspond to the diameter of the nanopost NP. When the first nanoposts NP1 and the second nanoposts NP2 each have a cross-sectional shape other than a circle, the width of the nanopost NP may correspond to a relatively small width in the cross-sectional shape. Hereinafter, an example in which the first nanoposts NP1 and the second nanoposts NP2 are formed in a circular cross-sectional shape will be described, and the size of each of the first nanoposts NP1 and the second nanoposts NP2 corresponds to the cross-sectional area or width (diameter), but is not limited thereto.

Referring to FIG. 5B, the sizes of the second nanoposts NP2 disposed in the pixel corresponding regions 131, 132, 133, and 134 may be in the order Pb>Pc>Pa. For example, the cross-sectional area of the nanopost Pa disposed in each of the first green pixel corresponding region 131 and the second green pixel corresponding region 134 may be smaller than the cross-sectional area of the nanopost Pb disposed in the blue pixel corresponding region 132 or the cross-sectional area of the nanopost Pc disposed at the center of the red pixel corresponding region 133. The cross-sectional area of the nanopost Pc disposed in the red pixel corresponding region 133 may be larger than the cross-sectional area of the nanopost Pb disposed in the blue pixel corresponding region 132. In addition, in the first green pixel corresponding region 131 and the second green pixel corresponding region 134, the four nanoposts Pa may be disposed to be moved outward at positions away and spaced apart from the center and symmetrically disposed respectively as the second nanoposts NP2, and in the red pixel corresponding region 133, the four nanoposts Pc may be disposed to be moved outward at positions away and spaced apart from the center and symmetrically disposed respectively as the second nanoposts NP2. In the blue pixel corresponding region 132, one nanopost Pb may be disposed at the center as the second nanopost NP2. However, this is only one example, and second nanoposts NP2 of various shapes, sizes (widths), and arrangements may be applied as needed.

The first nanoposts NP1 disposed in the pixel corresponding regions 131, 132, 133, and 134 may be arranged in different arrangement and cross-sectional size (width) distribution from the second nanoposts NP2. For example, the first nanoposts NP1 provided in the first green pixel corresponding region 131 and the second green pixel corresponding region 134 may have different distribution rules in the first direction (X direction) and the second direction (Y direction). For example, in the first green pixel corresponding region 131 and the second green pixel corresponding region 134, nanoposts as the first nanoposts NP1 may be disposed adjacent to the nanopost Pa in the first direction (X direction) and the second direction (Y direction) in the first green pixel corresponding region 131, and may be disposed adjacent to the nanopost Pa in the second direction (Y direction) and the first direction (X direction) in second green pixel corresponding region 134. In addition, the nanoposts disposed adjacent in the second direction (Y direction) may be disposed in a direction away and spaced apart from the nanopost Pa compared to the nanoposts disposed adjacent in the first direction (X direction). The nanoposts (hereinafter referred to as boundary nanoposts) may be disposed to correspond to adjacent nanoposts on a boundary line between the first green pixel corresponding region 131 and the blue pixel corresponding region 132 and a boundary line between the second green pixel corresponding region 134 and the red pixel corresponding region 133 in the first direction (X direction), and the boundary nanoposts may be disposed to correspond to adjacent nanoposts on a boundary line between the first green pixel corresponding region 131 and the red pixel corresponding region 133 and a boundary line between the second green pixel corresponding region 134 and the blue pixel corresponding region 132 in the second direction (Y direction) In the blue pixel corresponding region 132, first sub nanoposts as the first nanoposts NP1 may be disposed to correspond to the boundary nanoposts in the first direction (X direction) and the second direction (Y direction) and disposed in a direction closer to the nanopost Pb. Accordingly, eight first sub nanoposts as the first nanoposts NP1 may be disposed in the blue pixel corresponding region 132. In addition, in the blue pixel corresponding region 132, second sub nanoposts as the first nanoposts NP1 may be disposed in the first direction (X direction) and the second direction (Y direction) at positions which do not correspond to the first sub nanoposts. Four second sub nanoposts may be disposed in the blue pixel corresponding region 132. The first sub nanopost and the second sub nanopost may have different cross-sectional sizes. For example, the first sub nanopost may have a smaller cross-sectional size than the second sub nanopost.

The nanopost Pb disposed in the blue pixel corresponding region 132 may have greatest cross-sectional area among the second nanoposts NP2 disposed in the pixel corresponding regions 131, 132, 133, and 134, that is, the nanoposts Pa, the nanopost Pb, and the nanoposts Pc. In addition, the first sub nanopost may have minimum cross-sectional size among the first nanoposts NP1 disposed in the pixel corresponding regions 131, 132, 133, and 134. For example, among the first nanoposts NP1 and the second nanoposts NP2 disposed in the pixel corresponding regions 131, 132, 133, and 134, the first nanopost NP1 having minimum cross-sectional area, and the second nanopost NP2 having greatest cross-sectional area may be disposed in the blue pixel corresponding region 132.

The arrangement of the first nanoposts NP1 disposed in the pixel corresponding regions 131, 132, 133, and 134 shown in FIG. 5B is only an example, and the first nanoposts NP1 having various shapes, sizes (widths), and arrangements may be applied as needed.

The distribution of the first nanoposts NP1 and the second nanoposts NP2 illustrated in FIG. 5B is due to a pixel arrangement of the Bayer pattern. In both the blue pixel 112 and the red pixel 113, pixels adjacent to each other in the first direction (X direction) and the second direction (Y direction) are the same as the green pixels 111 and 114, while adjacent pixels of the first green pixel 111 in the first direction (X direction) and in the second direction (Y direction) are different from each other as the blue pixel 112 and the red pixel 113, and adjacent pixels of the second green pixel 114 in the first direction (X direction) and in the second direction (Y direction) are different from each other as the red pixel 113 and the blue pixel 114. In addition, the first green pixel 111 and the second green pixel 114 are adjacent to green pixels in four diagonal directions, the blue pixel 112 is adjacent to the red pixels 113 in four diagonal directions, and the red pixel 113 is adjacent to the blue pixels 112 in four diagonal directions. Therefore, in the blue pixel corresponding region 132 and the red pixel corresponding region 133 corresponding to the blue pixel 112 and the red pixel 113, the first nanoposts NP1 and the second nanoposts NP2 are arranged in the form of 4-fold symmetry, and in the first green pixel corresponding region 131 and the second green pixel corresponding region 134, the first nanoposts NP1 and the second nanoposts NP2 are arranged in the form of 2-fold symmetry. For example, the first green pixel corresponding region 131 and the second green pixel corresponding region 134 are rotated by 90 degrees with respect to each other.

FIG. 5B shows that the first nanoposts NP1 and the second nanoposts NP2 all have a symmetrical circular cross-sectional shape, but may include some nanoposts having an asymmetrical cross-sectional shape. For example, nanoposts having asymmetrical cross-sectional shapes with different widths in the first direction (X direction) and the second direction (Y direction) may be employed in the first green pixel corresponding region 131 and the second green pixel corresponding region 134, and nanoposts having symmetrical cross-sectional shapes with the same width in the first direction (X direction) and the second direction (Y direction) may be employed in the blue pixel corresponding region 132 and the red pixel corresponding region 133.

Referring again to FIGS. 4A and 4B, an etch stop layer may be further provided below the color separating lens array 130. The etch stop layer may be disposed between the spacer layer 120 and the color separating lens array 130 to prevent the spacer layer 120 from being damaged during a process of forming the color separating lens array 130. The etch stop layer may be an hafnium oxide (HfO₂) film and may be formed over the entire area of the color separating lens array 130. The etch stop layer may have a thickness that performs a lower layer protection function without impairing the optical characteristics of the color separating lens array 130, and may have the thickness of, for example, about 3 nm to about 30 nm or about 5 nm to about 15 nm.

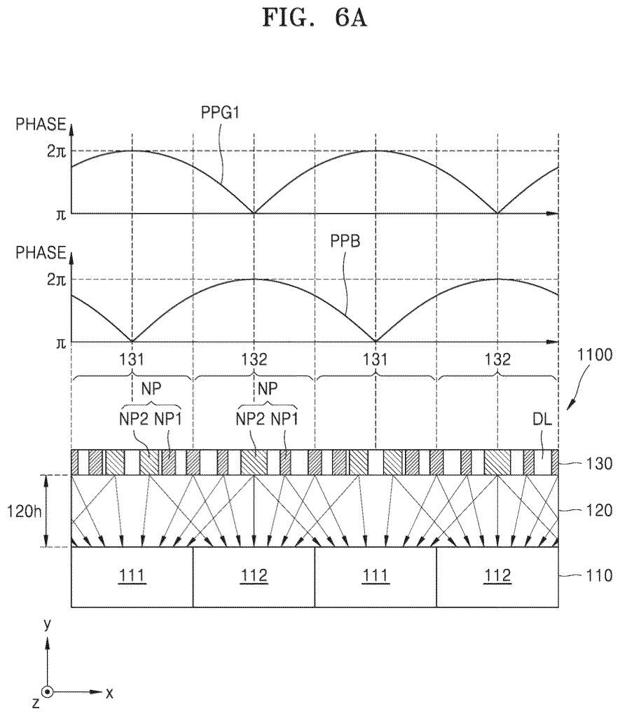

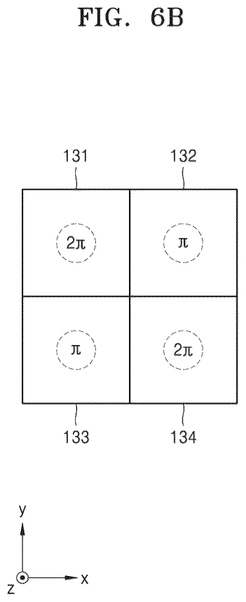

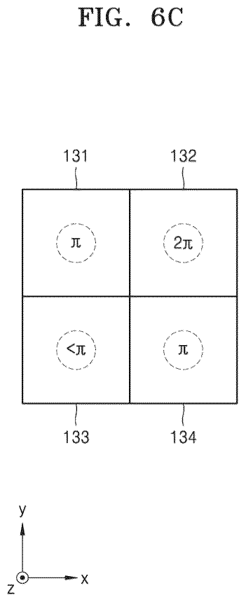

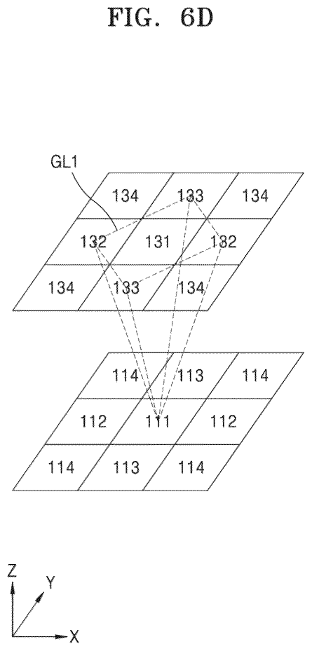

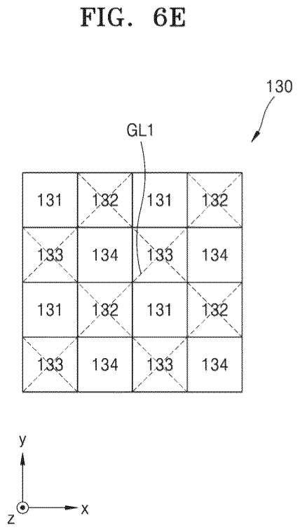

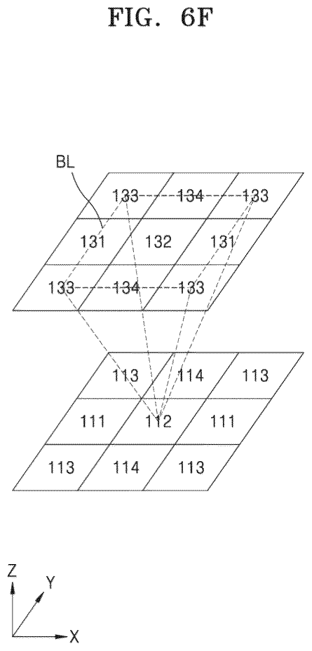

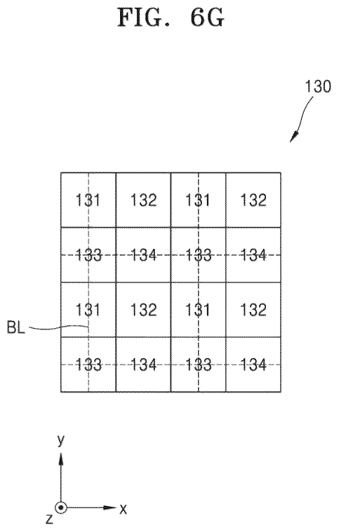

FIG. 6A shows phase profiles of green light and blue light passing through the color separating lens array 130 along line A-A′ of FIG. 5B. FIG. 6B shows a phase of green light passing through the color separating lens array 130 at the centers of the pixel corresponding regions 131, 132, 133, and 134. FIG. 6C shows a phase of blue light passing through the color separating lens array 130 at the centers of the pixel corresponding regions 131, 132, 133, and 134. The phase profiles of green light and blue light in FIG. 6A are similar to phase profiles of a first wavelength light and a second wavelength light illustrated in FIG. 3B.

Referring to FIGS. 6A and 6B, the green light passing through the color separating lens array 130 may have a first green light phase profile PPG1 that is greatest at the center of the first green pixel corresponding region 131, and is reduced in a direction away and spaced apart from the center of the first green pixel corresponding region 131. For example, at a position immediately after passing through the color separating lens array 130, at a lower surface of the color separating lens array 130 or an upper surface of the spacer layer 120, the phase of green light is greatest at the center of the first green pixel corresponding region 131 and is gradually reduced in a concentric circle away and spaced apart from the center of the first green pixel corresponding region 131, so that the phase of green light is minimum at the center of the blue pixel corresponding region 132 and the red pixel corresponding region 133 in the first direction (X direction) and second direction (Y direction), and is minimum at a contact point of the first green pixel corresponding region 131 and the second green pixel corresponding region 134 in a diagonal direction. When the phase of the green light is set as 2π with respect to light emitted from the center of the first green pixel corresponding region 131, the green light with the phase of about 0.9π to about 1.1π may be emitted from the center of the blue pixel corresponding region 132 and the red pixel corresponding region 133, the green light with the phase of 2π may be emitted from the center of the second green pixel corresponding region 134, and the green light with the phase of about 1.1π to about 1.5π may be emitted from the contact point between the first green pixel corresponding region 131 and the second green pixel corresponding region 134. Accordingly, a phase difference between the green light passing through the center of the first green pixel corresponding region 131 and the green light passing through the centers of the blue pixel corresponding region 132 and the red pixel corresponding region 133 may be about 0.9π to about 1.1 π.

The first green light phase profile PPG1 does not indicate that the amount of phase delay of light passing through the center of the first green pixel corresponding region 131 is the greatest, and may be a value remaining after removing 2n π, that is, a profile of a wrapped phase, when the phase delay of light passing through another position is greater and has a value greater than 2π by setting the phase of light passing through the first green pixel corresponding region 131 to 2π. For example, when the phase of light passing through the center of the blue pixel corresponding region 132 is 3π by setting the phase of light passing through the first green pixel corresponding region 131 to 2π, the phase of light in the blue pixel corresponding region 132 may be π remaining by removing 2π (when n=1) from 3 π

Referring to FIGS. 6A and 6C, the blue light passing through the color separating lens array 130 may have a blue light phase profile PPB that is greatest at the center of the blue pixel corresponding region 132, and is reduced in a direction away and spaced apart from the center of the blue pixel corresponding region 132. For example, at a position immediately after passing through the color separating lens array 130, at a lower surface of the color separating lens array 130 or an upper surface of the spacer layer 120, the phase of blue light is greatest at the center of the blue pixel corresponding region 132 and is gradually reduced in a concentric circle away and spaced apart from the center of the blue pixel corresponding region 132, so that the phase of blue light becomes minimum at the center of the first green pixel corresponding region 131 and the second green pixel corresponding region 134 in the first direction (X direction) and second direction (Y direction), becomes minimum at the center of the red pixel corresponding region 133 in the diagonal direction. When the phase of the blue light at the center of the blue pixel corresponding region 132 is 2π, the phase of blue light at the center of the first green pixel corresponding region 131 and the second green pixel corresponding region 134 may be, for example, about 0.9π to about 1.1π, and the phase of blue light at the center of the red pixel corresponding region 133 may have a value less than the phase of blue light at the center of the first green pixel corresponding region 131 and the second green pixel corresponding region 134, for example, about 0.5π to about 0.9 π.

FIG. 6D exemplarily illustrates a proceeding direction of green light incident on a first green light concentration region GL1. FIG. 6E exemplarily illustrates an array of the first green light concentration region GL1.

The green light incident on the periphery of the first green pixel corresponding region 131 is concentrated on the first green pixel 111 by the color separating lens array 130, as shown in FIG. 6D, and the green light from blue pixel corresponding region 132 and the red pixel corresponding region 133, other than the first green pixel corresponding region 131, is incident on the first green pixel 111. For example, the phase profile of green light described with reference to FIGS. 6A and 6B allows to be concentrated on the first green pixel 111 green light in which passing through the first green light concentration region GL1 connecting the centers of the two blue pixel corresponding regions 132 and the two red pixel corresponding regions 133 which are adjacent to the first green pixel corresponding region 131 with one side facing each other. Therefore, as shown in FIG. 6E, the color separating lens array 130 may operate as an array of the first green light concentration region GL1 that concentrates the green light on the first green pixel 111. The first green light concentration region GL1 may have a larger area than that of the corresponding first green pixel 111, for example, about 1.2 times to about 2 times.

FIG. 6F exemplarily illustrates a proceeding direction of blue light incident on a blue light concentration region BL. FIG. 6G exemplarily illustrates an array of the blue light concentration region BL.

The blue light is concentrated by the color separating lens array 130 on the blue pixel 112 as shown in FIG. 6F, and the blue light from the pixel corresponding regions 131, 132, 133, and 134 is incident on the blue pixel 112. The phase profile of blue light described with reference to FIGS. 6A and 6C are concentrated on the blue pixel 112 passing through the blue light concentration region BL formed by connecting the centers of the four red pixel corresponding regions 133 adjacent to the blue pixel corresponding region 132 facing vertices. Therefore, as shown in FIG. 6G, the color separating lens array 130 may operate as an array of the blue light concentration region BL that concentrates the blue light on the blue pixel 112. The blue light concentration region BL may have a larger area than that of the corresponding blue pixel 112, for example, about 1.5 times to about 4 times. A part of the blue light concentration region BL may overlap with the first green light concentration region GL1 described above and a second green light concentration region GL2 and a red light concentration region RL described below.

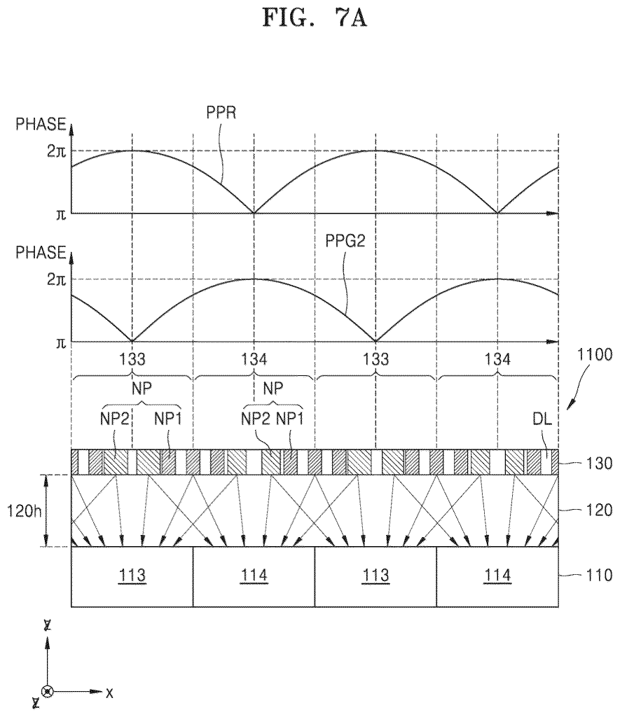

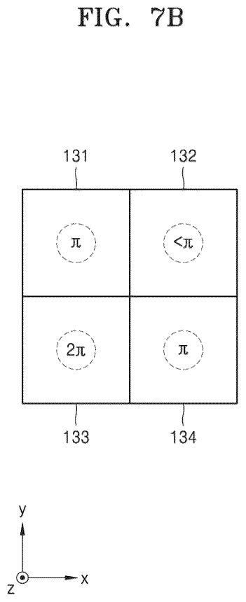

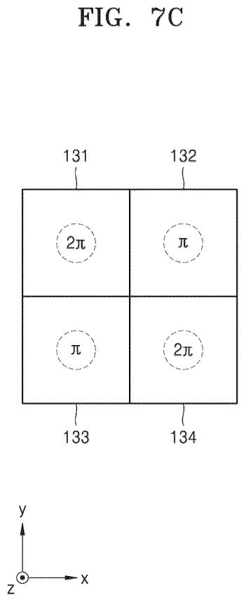

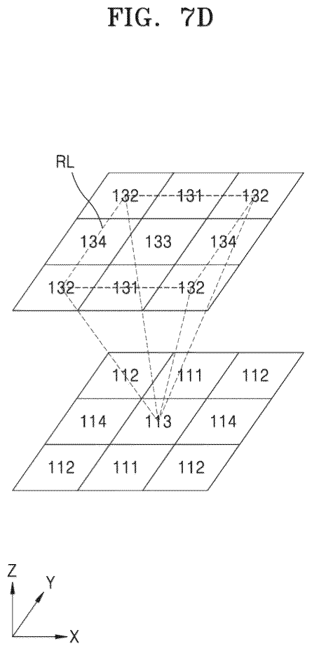

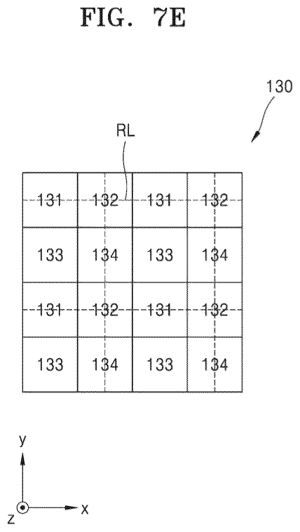

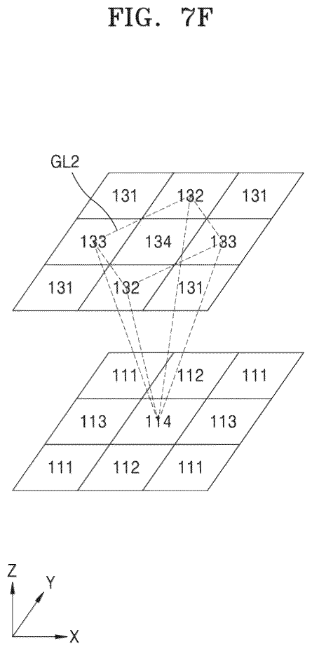

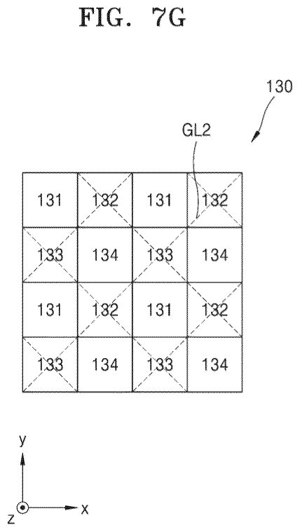

FIG. 7A shows phase profiles of green light and red light passing through the color separating lens array 130 along line B-B′ in FIG. 5B. FIG. 7B shows a phase of red light passing through the color separating lens array 130 at the centers of the pixel corresponding regions 131, 132, 133, and 134. FIG. 7C shows a phase of green light passing through the color separating lens array 130 at the centers of the pixel corresponding regions 131, 132, 133, and 134.

Referring to FIGS. 7A and 7B, the red light passing through the color separating lens array 130 may have a phase profile PPR that is greatest at the center of the red pixel corresponding region 133, and is reduced in a direction away and spaced apart from the center of the red pixel corresponding region 133. For example, at a position immediately after passing through the color separating lens array 130, at a lower surface of the color separating lens array 130 or an upper surface of the spacer layer 120, the phase of red light is greatest at the center of the red pixel corresponding region 133 and is gradually reduced in a concentric circle away and spaced apart from the center of the red pixel corresponding region 133, so that the phase of red light is minimum at the center of the first green pixel corresponding region 131 and the second green pixel corresponding region 134 in the first direction (X direction) and second direction (Y direction), and is minimum at the center of the blue pixel corresponding region 132 in a diagonal direction. When the phase of the red light at the center of the red pixel corresponding region 133 is 2π, the phase of the red light at the center of the first green pixel corresponding region 131 and the second green pixel corresponding region 134 may be, for example, about 0.9π to about 1.1π, and the phase of the red light at the center of the blue pixel corresponding region 132 may have a value less than the phase of red light at the center of the first green pixel corresponding region 131 and the second green pixel corresponding region 134, for example, about 0.6π to about 0.9 π.

Referring to FIGS. 7A and 7C, the green light passing through the color separating lens array 130 may have a second green light phase profile PPG2 that is greatest at the center of the second green pixel corresponding region 134, and is reduced in a direction away and spaced apart from the center of the second green pixel corresponding region 134. Upon comparing the first green light phase profile PPG1 of FIG. 6A with the second green light phase profile PPG2 of FIG. 7A, the second green light phase profile PPG2 is the same as the first green light phase distribution PPG1 moved in parallel by one pixel pitch in the first direction (X direction) and the second direction (Y direction). For example, the first green light phase profile PPG1 has greatest phase at the center of the first green pixel corresponding region 131, while the second green light phase profile PPG2 has greatest phase at the center of the second green pixel corresponding region 134 apart from the center of the first green pixel corresponding region 131 by one pixel pitch in the first direction (X direction) and the second direction (Y direction). The phase profiles of FIGS. 6B and 7C showing the phases at the centers of the pixel corresponding regions 131, 132, 133, and 134 may be the same. Regarding the phase profile of green light with respect to the second green pixel corresponding region 134, when the phase of the green light is set as 2π with respect to light emitted from the center of the second green pixel corresponding region 134, the green light with the phase of about 0.9π to about 1.1π may be emitted from the center of the blue pixel corresponding region 132 and the red pixel corresponding region 133, the green light with the phase of 2π may be emitted from the center of the first green pixel corresponding region 131, and the green light with the phase of about 1.1π to about 1.5π may be emitted from the contact point between the first green pixel corresponding region 131 and the second green pixel corresponding region 134.

FIG. 7D exemplarily illustrates a proceeding direction of red light incident on the red light concentration region RL. FIG. 7E exemplarily illustrates an array of the red light concentration region RL.

The red light is concentrated on the red pixel 113 by the color separating lens array 130 as shown in FIG. 7D, and red light from the pixel corresponding region 131, 132, 133, and 134 is incident on the red pixel 113. The phase profile of red light described with reference to FIGS. 7A and 7B are concentrated on the red pixel 113 passing through the red light concentration region RL formed by connecting the centers of the four blue pixel corresponding regions 132 adjacent to the red pixel corresponding regions 133 facing vertices. Therefore, as shown in FIG. 7E, the color separating lens array 130 may operate as an array of the red light concentration region RL that concentrates the red light on the red pixel 113. The red light concentration region RL may have a larger area than that of the corresponding red pixel 113, for example, about 1.5 times to about 4 times. A part of the red light concentration region RL may overlap with the first green light concentration region GL1, the second green light concentration region GL2, and the blue light concentration region BL.

Referring to FIGS. 7F and 7G, the green light incident on the periphery of the second green pixel corresponding region 134 proceeds similar to that described with respect to the green light incident on the periphery of the first green pixel corresponding region 131, and is concentrated on the second green pixel 114, as shown in FIG. 7F. Accordingly, as shown in FIG. 7G, the color separating lens array 130 may operate as an array of the second green light concentration region GL2 that concentrates the green light on the second green pixel 114. The second green light concentration region GL2 may have a larger area than that of the corresponding second green pixel 114, for example, about 1.2 times to about 2 times.

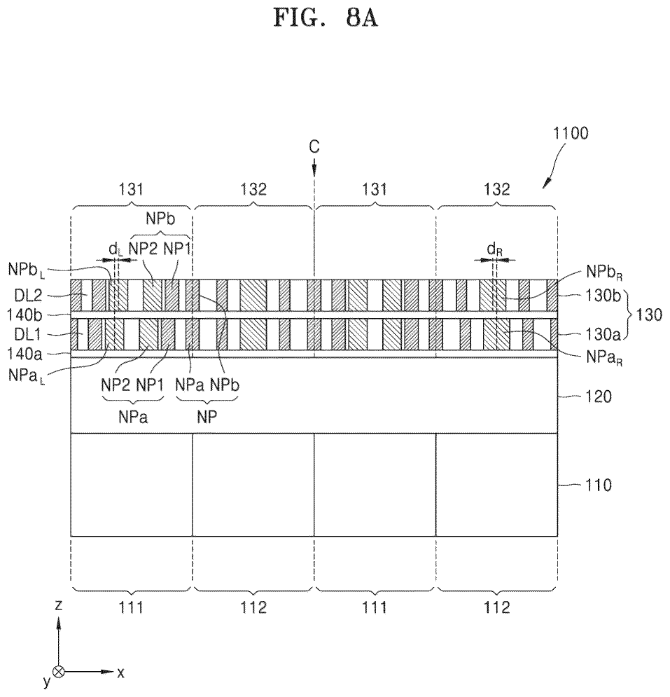

FIGS. 8A and 8B are schematic different cross-sectional views of a pixel array 1100 of an image sensor 1000 according to another embodiment and differ from FIGS. 4A and 4B in that a color separating lens array 130 includes a plurality of color separating lens layers 130a and 130b. Here, the same members as in FIGS. 4A and 4B are indicated by the same reference numerals, and repetitive descriptions of the same members are omitted as much as possible.

Referring to FIGS. 8A and 8B, the pixel array 1100 of the image sensor 1000 according to the embodiment includes a sensor substrate 110 including a plurality of pixels 111, 112, 113, and 114 that sense light, a transparent spacer layer 120 disposed on the sensor substrate 110, and a color separating lens array 130 disposed on the spacer layer 120. The color separating lens array 130 may be supported by the spacer layer 120, and may include a plurality of color separating lens layers including nanoposts NP, such as first color separating lens layer 130a and second color separating lens layer 130b. In FIGS. 8A and 8B, NPa denotes nanopost NP of the first color separating lens layer 130a, and NPb denotes nanopost NP of the second color separating lens layer 130b. The first color separating lens layer 130a of the color separating lens array 130 may include the nanoposts NPa which includes high refractive material, and a first dielectric layer DL1 which is a low refractive material filled in spaces between the nanoposts NPa. In addition, the second color separating lens layer 130b of the color separating lens array 130 may include the nanoposts NPb which includes high refractive material, and a second dielectric layer DL2 which is a low refractive material filled in spaces between the nanoposts NPb. A refractive index of the high refractive material is greater than a refractive index of the low refractive material. For example, the first dielectric layer DL1 and the second dielectric layer DL2 may each include a dielectric material with a lower refractive index than that of a material of each of the nanoposts NPa and NPb, for example, air or SiO₂.

The first color separating lens layer 130a may include the nanoposts NPa in the pixel corresponding regions 131, 132, 133, and 134. The nanoposts NPa may be disposed in a symmetrical structure on a boundary line between pixels, and may not be disposed at an intersection of pixel boundary lines. The nanoposts NPa may include first nanopost NP1 and second nanopost NP2. As described above, the first nanopost NP1 may represent a nanopost with a relatively small width that may be obtained through first patterning as described above, the first nanoposts NP1 may correspond to a nanopost in a size range that at least partially requires consideration of the influence of an exposure diffraction limit, and at least one of the first nanoposts NP1 may have a width of the exposure diffraction limit or less. The second nanopost NP2 may represent a nanopost having a relatively great width that may be obtained through second patterning as described above, and may have a width, for example, greater than the exposure diffraction limit.

The first nanoposts NP1 and the second nanoposts NP2 included in the first color separating lens layer 130a as the nanoposts NPa may be formed to have sizes, shapes, and/or arrangements as described above with reference to FIG. 5B. The nanoposts NPa may all have a symmetrical circular cross-sectional shape, or may include some nanoposts having an asymmetrical cross-sectional shape. For example, nanoposts having asymmetrical cross-sectional shapes with different widths in first direction (X direction) and second direction (Y direction) may be employed in the first green pixel corresponding region 131 and the second green pixel corresponding region 134, and nanoposts having symmetrical cross-sectional shapes with the same width in the first direction (X direction) and the second direction (Y direction) may be employed in the blue pixel corresponding region 132 and the red pixel corresponding region 133.

The shapes and arrangement of the nanoposts NPb included in the second color separating lens layer 130b may be similar to those of the first color separating lens layer 130a. For example, the second color separating lens layer 130b may include the nanoposts NPb in the pixel corresponding regions 131, 132, 133, and 134. The nanoposts NPb may be disposed in a symmetrical structure on a boundary line between pixels, and may not be disposed at an intersection of pixel boundary lines. The nanoposts NPb may include first nanopost NP1 and second nanopost NP2. The first nanopost NP1 may represent a nanopost with a relatively small width that may be obtained through first patterning as described above, the first nanoposts NP1 may correspond to a nanopost in a size range that at least partially requires consideration of the influence of an exposure diffraction limit, and at least one of the first nanoposts NP1 may have a width of the exposure diffraction limit or less. The second nanopost NP2 may represent a nanopost having a relatively great width that may be obtained through second patterning as described above, and may have a width, for example, greater than the exposure diffraction limit.

The first nanoposts NP1 and the second nanoposts NP2 included in the second color separating lens layer 130b as the nanoposts NPb may be formed to have sizes, shapes, and/or arrangements as described above with reference to FIG. 5B. However, the nanoposts NPb of the second color separating lens layer 130b may be shifted toward a center C of the color separating lens array 130 more than the nanoposts NPa of the first color separating lens layer 130a. For example, referring to FIG. 8A, nanoposts NPb_{R} arranged on the right side of the second color separating lens layer 130b may be shifted by d_{R} toward the center C of the color separating lens array 130 more than nanoposts NPa_{R} of the corresponding first color separating lens layer 130a, and nanoposts NPb_{L} arranged on the left side of the second color separating lens layer 130b may be shifted by d_{L} toward the center C of the color separating lens array 130 more than nanoposts NPa_{L} of the corresponding first color separating lens layer 130a. The reason why the second color separating lens layer 130b includes the shifted nanoposts NPb is because a chief ray incident on the color separating lens array 130 has different angles according to positions, and a shift amount of the nanoposts NPb may be proportional to a distance from the center C of the color separating lens array 130. For example, as the distance from the center C of the color separating lens array 130 increases, the amount of the nanoposts NPb shifted toward the center C of the color separating lens array 130 may increase. The second color separating lens layer 130b may include a smaller or larger number of the nanoposts NPb than the nanoposts NPa formed in the first color separating lens layer 130a. For example, the nanoposts NPa are formed on the boundary line between the green pixel corresponding region 131 and the red pixel corresponding region 133 of the first color separating lens layer 130a and a boundary line between the green pixel corresponding region 134 and the blue pixel corresponding region 132 of the first color separating lens layer 130a, but the nanoposts NPb may not be formed on the second color separating lens layer 130b at the corresponding position.

Referring again to FIGS. 8A and 8B, a first etch stop layer 140a and a second etch stop layer 140b may be respectively provided below the first color separating lens layer 130a and the second color separating lens layer 130b. The first etch stop layer 140a may be disposed between the spacer layer 120 and the first color separating lens layer 130a to prevent the spacer layer 120 from being damaged by a process of forming the first color separating lens layer 130a, and the second etch stop layer 140b may be disposed between the first color separating lens layer 130a and the second color separating lens layer 130b to prevent the first color separating lens layer 130a from being damaged by a process of forming the second color separating lens layer 130b. The first etch stop layer 140a and the second etch stop layer 140b each may be an HfO₂ film and may be formed over the entire area of the color separating lens array 130. The first etch stop layer 140a and the second etch stop layer 140b each may have a thickness by which a lower layer protection function may be performed without impairing the optical characteristics of the color separating lens array 130, and may have the thickness of, for example, about 3 nm to about 30 nm or about 5 nm to about 15 nm.

Even when the color separating lens array 130 includes the plurality of color separating lens layers 130a and 130b as shown in FIGS. 8A and 8B, similar to the case where the color separating lens array 130 includes a single color separating lens layer described with reference to FIGS. 6A to 6G, incident light may be separated by wavelength and concentrated. For example, as described above with reference to FIG. 6A, green light passing through the plurality of color separating lens layers 130a and 130b of the color separating lens array 130 may have the first green light phase profile PPG1 that is greatest at the center of the first green pixel corresponding region 131, and is reduced in a direction away and spaced apart from the center of the first green pixel corresponding region 131, and blue light passing through the plurality of color separating lens layer 130a and 130b of the color separating lens array 130 may have the blue light phase profile PPB that is greatest at the center of the blue pixel corresponding region 132, and is reduced in a direction away and spaced apart from the center of the blue pixel corresponding region 132. In addition, as described above with reference to FIG. 6B, a phase difference between the green light passing through the center of the first green pixel corresponding region 131 and the green light passing through the centers of the blue pixel corresponding region 132 and the red pixel corresponding region 133 may be about 0.9π to about 1.1π. As described above with reference to FIG. 60, when the phase of the blue light at the center of the blue pixel corresponding region 132 is 2π, the phase of blue light at the center of the first green pixel corresponding region 131 and the second green pixel corresponding region 134 may be, for example, about 0.9π to about 1.1π, and the phase of blue light at the center of the red pixel corresponding region 133 may have a value less than the phase of blue light at the center of the first green pixel corresponding region 131 and the second green pixel corresponding region 134, for example, about 0.5π to about 0.9 π. As described above with reference to FIGS. 6D and 6E, the plurality of color separating lens layers 130a and 130b of the color separating lens array 130 may operate as an array of a first green light concentration region GL1 that concentrates the green light on the first green pixel 111. Also, as described above with reference to FIGS. 6F and 6G, the plurality of color separating lens layers 130a and 130b of the color separating lens array 130 may operate as an array of a blue light concentration region BL that concentrates the blue light on a blue pixel, and a part of the blue light concentration region BL may overlap with the first green light concentration region GL1 above described, a second green light concentration region GL2, and a red light concentration region RL described below.

In addition, even when the color separating lens array 130 includes the plurality of color separating lens layers 130a and 130b as shown in FIGS. 8A and 8B, similar to the case where the color separating lens array 130 includes a single color separating lens layer described with reference to FIGS. 7A to 7G, incident light may be separated by wavelength and concentrated. For example, as described above with reference to FIG. 7A, the red light passing through the color separating lens layers 130a and 130b of the color separating lens array 130 may have the phase profile PPR that is greatest at the center of the red pixel corresponding region 133, and is reduced in a direction away and spaced apart from the center of the red pixel corresponding region 133, and the green light passing through the color separating lens layers 130a and 130b of the color separating lens array 130 may have the second green light phase profile PPG2 that is greatest at the center of the second green pixel corresponding region 134, and is reduced in a direction away and spaced apart from the center of the second green pixel corresponding region 134. In addition, as described above with reference to FIG. 7B, when the phase of the red light at the center of the red pixel corresponding region 133 is 2π, the phase of the red light at the center of the first green pixel corresponding region 131 and the second green pixel corresponding region 134 may be, for example, about 0.9π to about 1.1π, as described above with reference to FIG. 7C, the phase of the red light at the center of the blue pixel corresponding region 132 may have a value less than the phase of red light at the center of the first green pixel corresponding region 131 and the second green pixel corresponding region 134, for example, about 0.6π to about 0.9π, and when the phase of the green light is set as 2π with respect to light emitted from the center of the second green pixel corresponding region 134, the green light with the phase of about 0.9π to about 1.1π may be emitted from the center of the blue pixel corresponding region 132 and the red pixel corresponding region 133, the green light with the phase of 2π may be emitted from the center of the first green pixel corresponding region 131, and the green light with the phase of about 1.1π to about 1.5π may be emitted from the contact point between the first green pixel corresponding region 131 and the second green pixel corresponding region 134. As described above with reference to FIGS. 7D and 7E, the plurality of color separating lens layers 130a and 130b of the color separating lens array 130 may operate as an array of a red light concentration region RL that concentrates the red light on a red pixel, and a part of the red light concentration region RL may overlap with the first green light concentration region GL1, the second green light concentration region GL2, and the blue light concentration region BL. Also, as described above with reference to FIGS. 7F and 7G, the plurality of color separating lens layers 130a and 130b of the color separating lens array 130 may operate as an array of the second green light concentration region GL2 that concentrates the green light on the second green pixel 114.

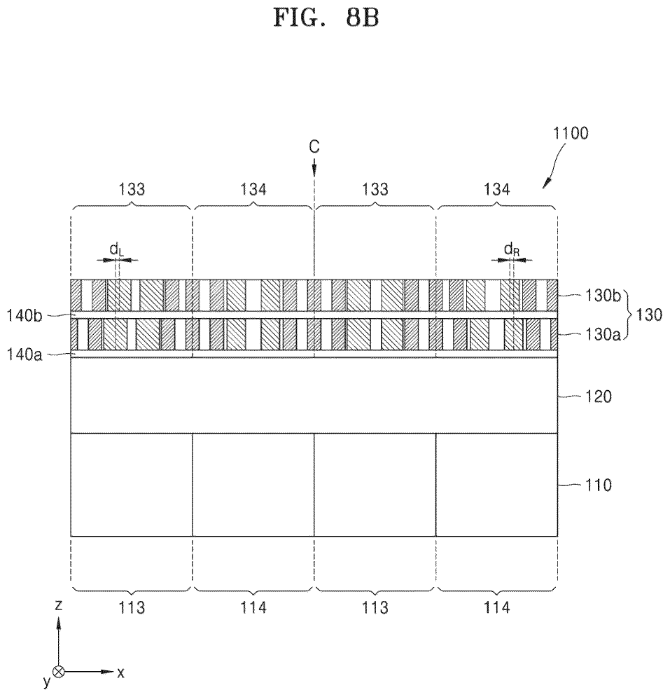

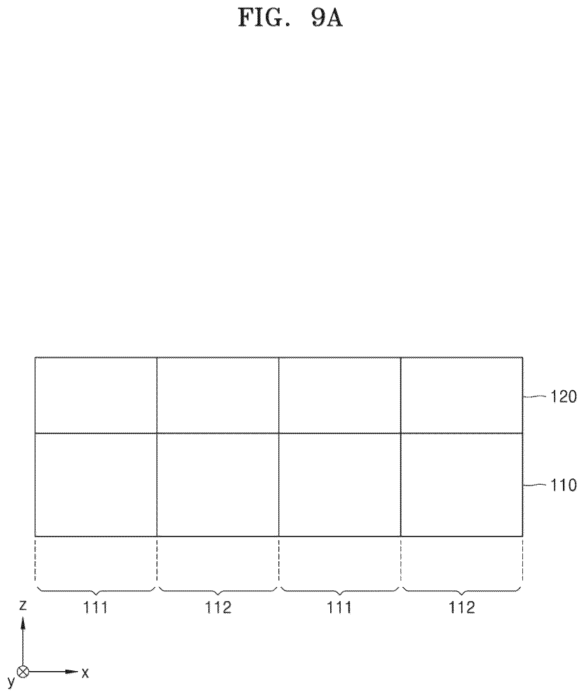

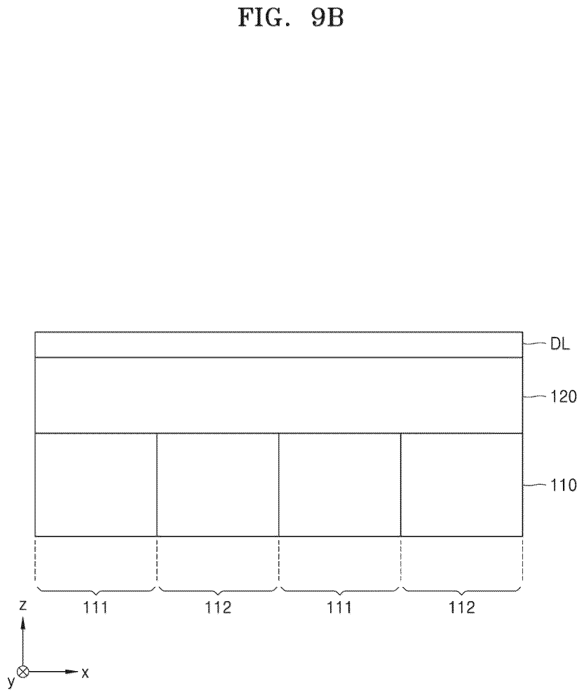

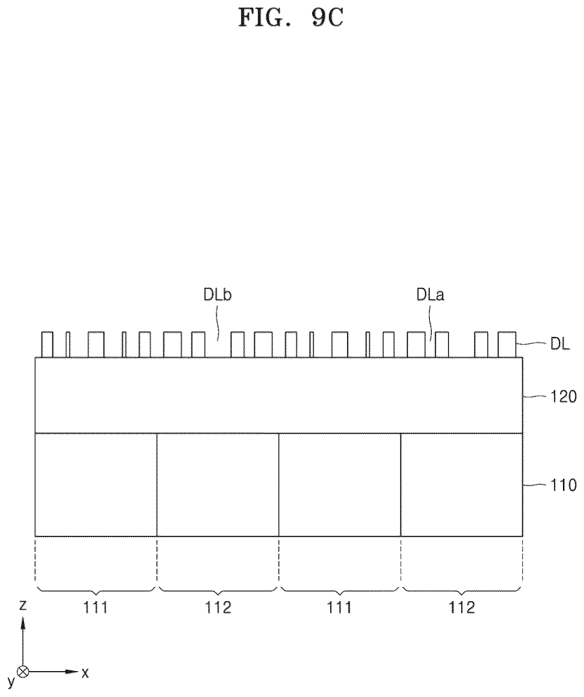

FIGS. 9A to 9D are diagrams for explaining a method of manufacturing the pixel array 1100 of the image sensor 1000 according to an example embodiment of FIGS. 4A and 4B.

First, as shown in FIG. 9A, a spacer 120 layer is formed on a sensor substrate 110. The spacer layer 120 may be, for example, a SiO₂ layer, and may be formed using various physical or chemical forming methods, such as thermal oxidation.

Next, as shown in FIG. 9B, a dielectric layer DL is formed on the spacer layer 120. The dielectric layer DL may be a SiO₂ layer. Here, an etch stop layer may be formed on the spacer layer 120, and the dielectric layer DL may be formed on the etch stop layer. At this time, the etch stop layer may include a material that may selectively etch the dielectric layer DL, that is, a material that is not etched by using a material used to etch the dielectric layer DL, for example, HfO₂. A HfO₂ layer may be formed by a physical or chemical forming method, such as PVD, CVD, PE-CVD, atomic layer deposition (ALD), etc.

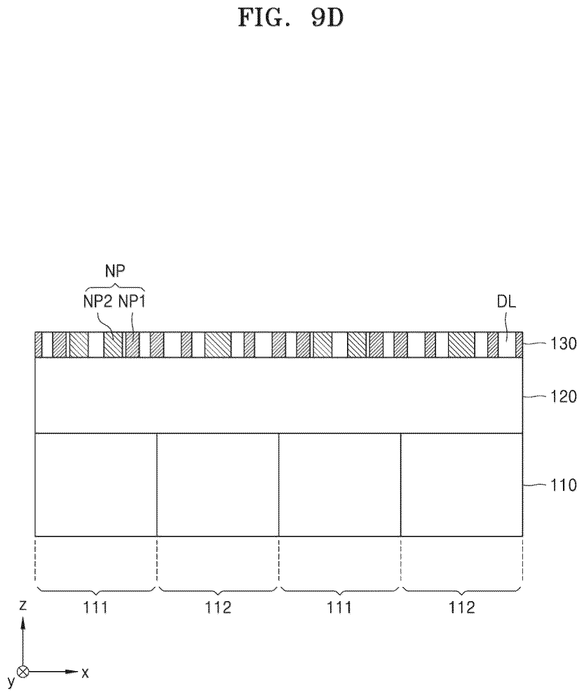

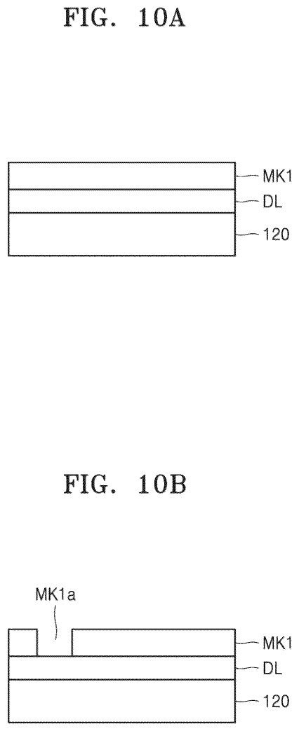

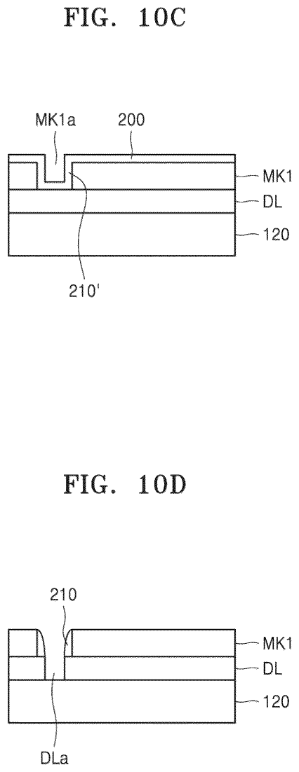

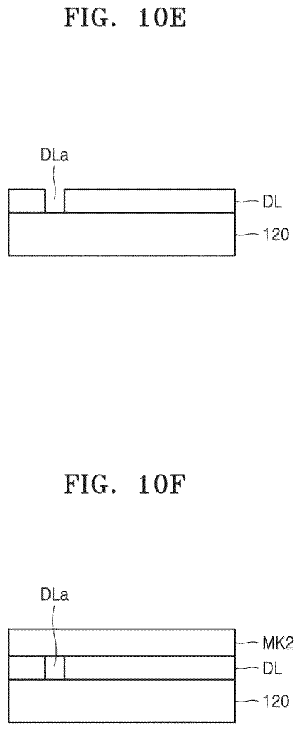

Next, as shown in FIG. 9C, engraved patterns DLa and DLb are formed on the dielectric layer DL through a patterning process including an exposure process. The engraved patterns DLa and DLb may be formed by forming a mask layer (MK1 in FIG. 10A), such as a photoresist layer, on the dielectric layer DL, patterning the mask layer through an exposure process, and then removing the exposed dielectric layer DL through an etching process, for example, a fluorine-based reactive ion etching process. The engraved patterns DLa and DLb may be formed through different patterning processes. For example, the engraved pattern DLa may be formed through a first patterning process, and the engraved pattern DLb may be formed through a second patterning process. In this way, the engraved patterns DLa and DLb may be formed through a double patterning process.

The engraved pattern DLa is for forming first nanoposts NP1 in a size range that includes a nanopost having a width of an exposure diffraction limit or less and at least partially requires consideration of the influence of the exposure diffraction limit, and, to this end, may be formed with a relatively small width, for example, a width close to the exposure diffraction limit, or a width of the exposure diffraction limit or less. The engraved pattern DLb is for forming second nanoposts NP2 in a size range that does not need to consider the influence of the exposure diffraction limit, and may be formed with a relatively great width, for example, a width greater than the exposure diffraction limit. As will be described below with reference to FIGS. 10A to 10K, the engraved pattern DLa may be formed during the first patterning process, and the engraved pattern DLb may be formed during the second patterning process. Meanwhile, when an etch stop layer is further provided between the spacer layer 120 and the dielectric layer DL, damage to the spacer layer 120 may be prevented by the etch stop layer during a process of etching the dielectric layer DL.

Next, as shown in FIG. 9D, nanoposts NP may be formed by filling the engraved patterns DLa and DLb formed on the dielectric layer DL with a nanostructure material. To this end, the engraved patterns DLa and DLb may be filled with a material having a different refractive index from that of the material of the dielectric layer DL, such as TiO₂, silicon oxynitride (SiON), HfO₂, etc., by using ALD.

The first nanoposts NP1 may be formed in a desired shape, size and/or arrangement by filling the engraved pattern DLa with the nanostructure material, and the second nanoposts NP2 may be formed in a desired shape, size and/or arrangement by filling the engraved pattern DLb with the nanostructure material. For example, the engraved patterns DLa and DLb may be formed through the first patterning process and the second patterning process to correspond to the shapes, sizes, and/or arrangements of the first nanoposts NP1 and the second nanopost NP2 as described with reference to FIG. 5B, and the first nanoposts NP1 and the second nanopost NP2 may be formed in the desired shape, size and/or arrangement by filling the engraved patterns DLa and DLb with the nanostructure material. In addition, the color separating lens array 130 of a single color separating lens layer structure may be formed by depositing a material on the dielectric layer DL and then removing the material through a chemical mechanical polishing (CMP) process.

FIGS. 9C and 9D exemplarily illustrates that the first nanoposts NP1 and the second nanopost NP2 are formed by forming the engraved patterns DLa and DLb through a double patterning process, and then filling the engraved patterns DLa and DLb with the nanostructure material in the same process operation simultaneously, but embodiments are not limited thereto. For example, the nanostructure material may be filled in different process operation to form the first nanopost NP1 and the second nanopost NP2. For example, the engraved pattern DLa may be formed in the first patterning process, and the first nanopost NP1 may be formed by filling the engraved pattern DLa with the nanostructure material, and the engraved pattern DLb may be formed in the second patterning process, and the second nanopost NP2 may be formed by filling the engraved pattern DLb with the nanostructure material.

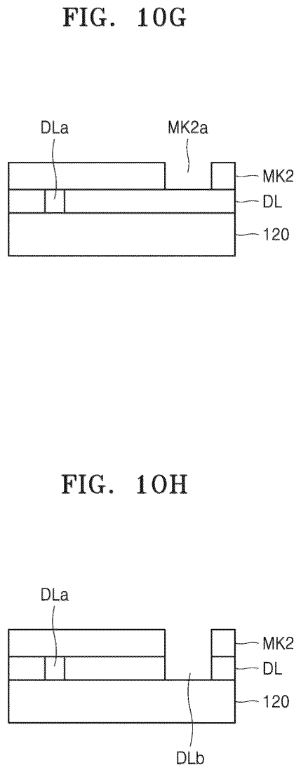

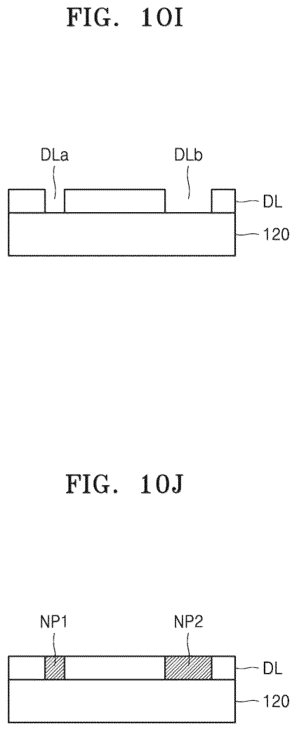

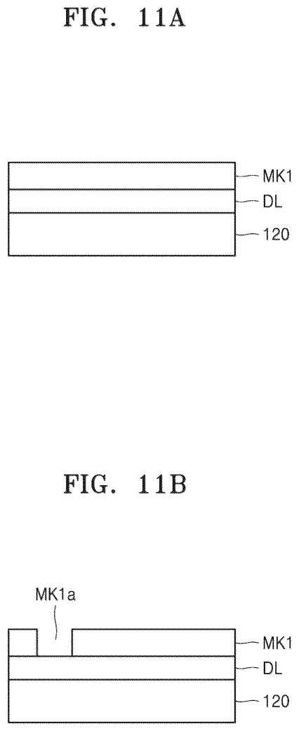

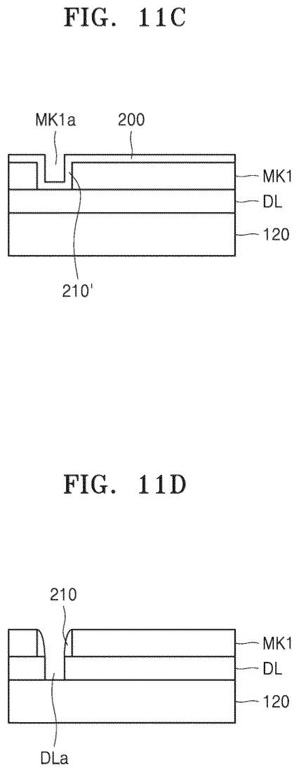

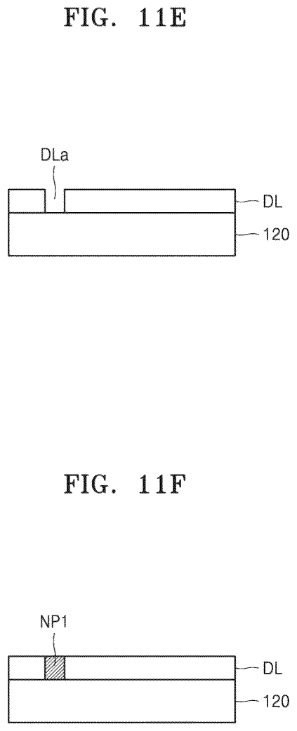

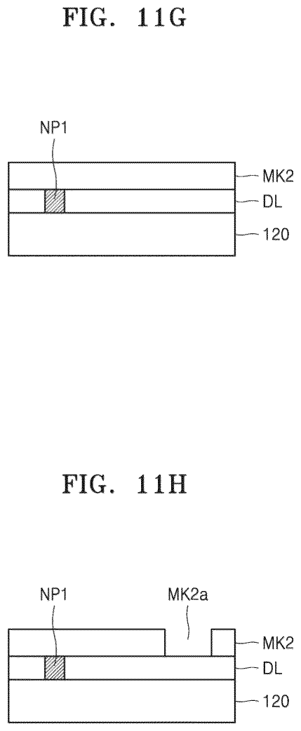

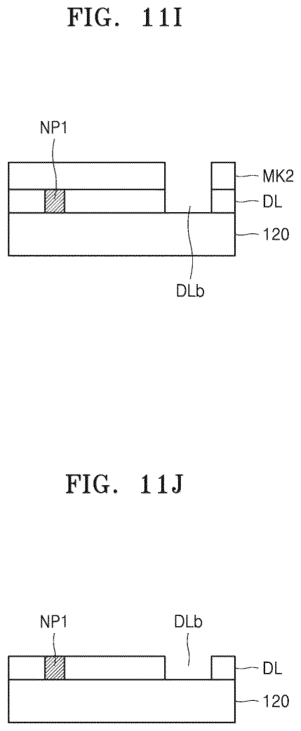

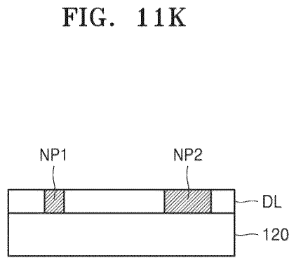

As shown in FIGS. 9C and 9D, when the first nanopost NP1 and the second nanopost NP2 are formed by filling the engraved patterns DLa and DLb with the same nanostructure material in the same process operation simultaneously, a manufacturing process of FIGS. 10A to 10J may be applied. As another example, when the first nanopost NP1 is formed by forming the engraved pattern DLa and filling the engraved pattern DLa with the nanostructure material, and then the second nanopost NP2 is formed by forming the engraved pattern DLb and filling the engraved pattern DLb with the nanostructure material, a manufacturing process shown in FIGS. 11A to 11K may be applied. For example, the nanostructure material filling operation to form the first nanopost NP1 and the nanostructure material filling operation to form the second nanopost NP2 may be separately performed.

FIGS. 10A to 10J illustrate manufacturing processes of forming a first nanopost NP1 and a second nanopost NP2 through a double patterning process. FIGS. 10A to 10E illustrate the manufacturing process of forming an engraved pattern DLa to form the first nanopost NP1 having a size range that requires consideration of the influence of an exposure diffraction limit, that is, a width close to the exposure diffraction limit, or a width of the exposure diffraction limit or less, and FIGS. 10F to 10I illustrate the manufacturing process of forming an engraved pattern DLb to form the second nanopost NP2 having a size range that does not need to consider the influence of the exposure diffraction limit, that is, a width greater than the exposure diffraction limit.

First, in order to form the engraved pattern DLa for forming the first nanopost NP1 in a dielectric layer DL, a first patterning process is performed as shown in FIGS. 10A to 10E.

Referring to FIG. 10A, the dielectric layer DL is formed on a spacer layer 120, and a mask layer MK1 is formed on the dielectric layer DL. Here, when an etch stop layer is provided between the spacer layer 120 and the dielectric layer DL, the etch stop layer may first be formed on the spacer layer 120, and then the dielectric layer DL may be formed on the etch stop layer. When the etch stop layer is further provided between the spacer layer 120 and the dielectric layer DL, during a process of etching the dielectric layer DL to form the engraved patterns DLa and DLb as shown in FIG. 9C, damage to the spacer layer 120 may be prevented.

The mask layer MK1 may be a photoresist layer. As another example, the mask layer MK1 may be formed as a stacked structure of at least one hard mask layer and a photoresist layer PR. The hard mask layer may include at least one of, for example, a first hard mask layer HM1 including a material having an etch selectivity compared to photoresist, or a second hard mask layers HM2 including a material having the etch selectivity and/or advantageous for etching of a high aspect ratio. The first hard mask layer HM1 may include, for example, a metal oxide such as silicon oxide (SiO₂) or HfO₂. The second hard mask layer HM2 may include, for example, an amorphous carbon layer (ACL), near frictionless carbon, etc.

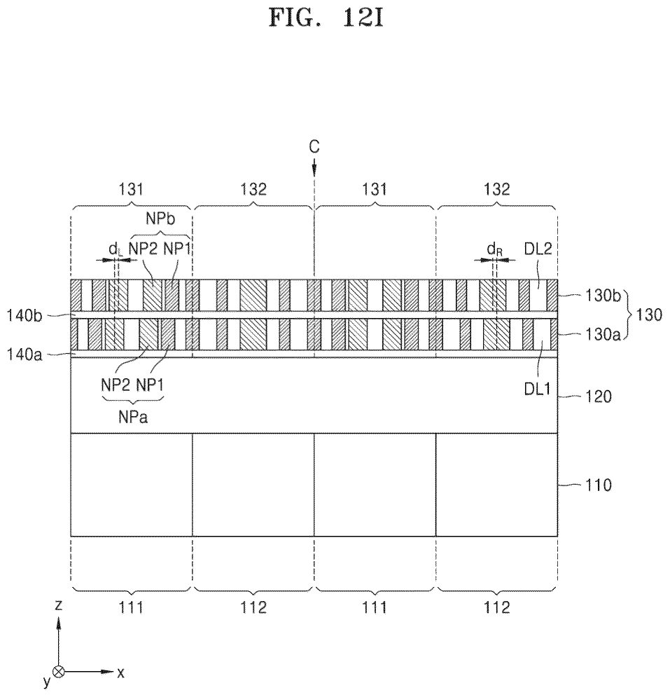

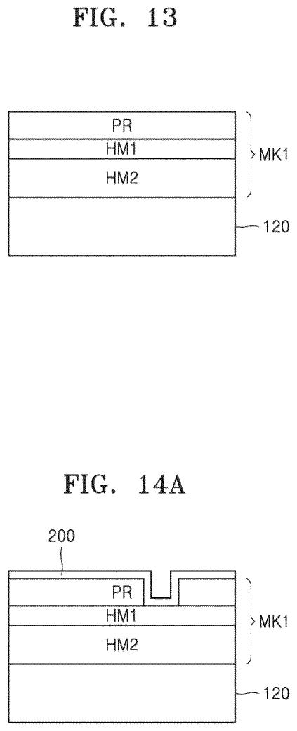

For example, the mask layer MK1 may include the photoresist layer PR, the first hard mask layer HM1, and the second hard mask layer HM2, as shown in FIG. 13. At this time, the mask layer MK1 may be stacked on the dielectric layer DL in the order of the second hard mask layer HM2, the first hard mask layer HM1, and the photoresist layer PR. As another example, the mask layer MK1 may be stacked on the dielectric layer DL in the order of the first hard mask layer HM1, the second hard mask layer HM2, and the photoresist layer PR. In addition, the mask layer MK1 may include one of the first hard mask layer HM1 and the second hard mask layer HM2 and the photoresist layer PR. In this case, the first hard mask layer HM1 or the second hard mask layer HM2 may be formed on the dielectric layer DL, and the photoresist layer PR may be formed thereon. Besides, the mask layer MK1 may be formed to include three or more hard mask layers and the photoresist layer PR.

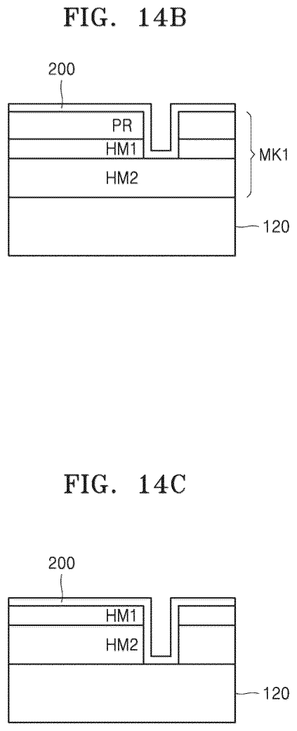

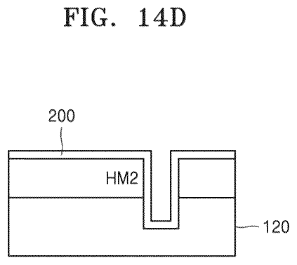

Next, as shown in FIG. 10B, an opening MK1a may be formed to correspond to the size, shape, and/or arrangement of the engraved pattern DLa to be formed at a position where the engraved pattern DLa is to be formed, through a patterning process including an exposure process for the mask layer MK1. Here, when the mask layer MK1 includes only the photoresist layer PR, the opening MK1a may be formed through the exposure process. At this time, the patterning process of the mask layer MK1 may represent the exposure process. When the mask layer MK1 includes the photoresist layer PR and at least one hard mask layer, a width or cross-sectional size of the opening MK1a may mean that it is formed through the exposure process, or is formed through the exposure process and a process of etching a hard mask layer (before forming a step cover layer 200, which will be described below) subsequent to the exposure process. For example, as may be inferred from FIGS. 11C, 11D, 14A, and 14B described below, when the mask layer MK1 includes the photoresist layer PR and at least one hard mask layer, and the step cover layer 200 is formed immediately after the exposure process or immediately after a process of etching a partial hard mask layer, due to a sidewall portion 210 of the step cover layer 200 left during an etching process, the width or cross-sectional size of the opening MK1a may be reduced from the etching process after forming the step cover layer 200. At this time, the patterning process of the mask layer MK1 may include the exposure process and a process of etching the hard mask layer subsequent to the exposure process. In this way, through the patterning process including the exposure process on the mask layer MK1, the opening MK1a may be formed at the position where the engraved pattern DLa is to be formed.

Accordingly, the width of the opening MK1a formed at the corresponding position may be greater than the width of the engraved pattern DLa in FIG. 9C. The shape of the opening MK1a may be formed to correspond to the shape of the engraved pattern DLa. For example, when the engraved pattern DLa is circular, the opening MK1a is also formed in a circular shape, and the width of the opening MK1a or the engraved pattern DLa may correspond to the diameter.

Next, as shown in FIG. 10C, a step cover layer 200 may be formed on the patterned mask layer MK1. The step cover layer 200 may be deposited as a layer with high step coverage by applying, for example, ALD. For example, the step cover layer 200 may be formed of the same material as the dielectric layer DL. Accordingly, the step cover layer 200 may be formed over an upper surface of the patterned mask layer MK1, a sidewall of the opening MK1a, and an upper region of the dielectric layer DL exposed by the opening MK1a. For example, the step cover layer 200 may form a sidewall 210′ within the opening MK1a.

Next, as shown in FIG. 10D, a process of etching the dielectric layer DL may be performed through the opening MK1a. During the etching process, the step cover layer 200 may be removed, and a portion of the dielectric layer DL exposed through the opening MK1a may be removed to form the engraved pattern DLa. The exposed dielectric layer DL may be removed through, for example, a fluorine-based reactive ion etching process to form the engraved pattern DLa. At this time, as a sidewall portion 210 of the step cover layer 200 withstands the etching process to be left, and the width or cross-sectional size of the final engraved pattern DLa may be reduced by the sidewall portion 210 of the step cover layer 200 left during the etching process. For example, the engraved pattern DLa with a width or cross-section size smaller than that of the opening MK1a may be formed. For example, when the opening MK1a has the size of the exposure diffraction limit, the engraved pattern DLa may be formed to be smaller than the exposure diffraction limit. Accordingly, the engraved pattern DLa may be formed to have the width less than the width of the opening MK1a, and a minimum width of the engraved pattern DLa may be the exposure diffraction limit or less.

FIGS. 10B, 10C, and 10D exemplarily illustrate that the step cover layer 200 is formed while the opening MK1a is formed in the mask layer MK1 to expose the dielectric layer DL, and the process of etching the dielectric layer DL is performed through the opening MK1a, but embodiments not limited thereto.

For example, when the mask layer MK1 includes a stacked structure of the photoresist layer PR and one hard mask layer, the step cover layer 200 may be formed immediately after a process of exposing the photoresist layer PR, immediately after a process of etching at least partial hard mask layer, or during the process of etching the dielectric layer DL, and the process of etching the dielectric layer DL may be performed through the opening MK1a. For example, when the mask layer MK1 includes a stacked structure of the photoresist layer PR and N hardmask layers (where N is a natural number greater than or equal to 2), the step cover layer 200 may be formed immediately after the process of exposing the photoresist layer PR, immediately after a process of etching a first hardmask layer, immediately after a process of etching Nth hardmask layer or during the process of etching the dielectric layer DL, and the process of etching the dielectric layer DL may be performed through the opening MK1a. Here, when a material layer exists between the opening MK1a and the dielectric layer DL, the existing material layer may be etched in advance for the process of etching the dielectric layer DL through the opening MK1a.

For example, as exemplarily illustrated in FIG. 13, the mask layer MK1 may include the photoresist layer PR, the first hard mask layer HM1, and the second hard mask layer HM2, the second hard mask layer HM2, the first hard mask layer HM1, and the photoresist layer PR may be sequentially stacked on the dielectric layer DL. In this case, as exemplarily illustrated in FIGS. 14A to 14D, the step cover layer 200 may be formed immediately after a process of exposing the photoresist layer PR or at any operation of a subsequent etching process.

For example, the step cover layer 200 may be formed immediately after the process of exposing the photoresist layer PR, as shown in FIG. 14A. The step cover layer 200 may be formed immediately after a process of etching the first hard mask layer HM1, as shown in FIG. 14B. The step cover layer 200 may be formed immediately after a process of etching the second hard mask layer HM2, as shown in FIG. 14C. As illustrated in FIG. 14C, the photoresist layer PR may be removed through the process of etching the second hard mask layer HM2. As shown in FIG. 14D, the step cover layer 200 may be formed in the middle of an etching process of the dielectric layer DL, and the etching process of the dielectric layer DL may be performed in several operations. As illustrated in FIG. 14D, the first hard mask layer HM1 may be removed through the etching process of the dielectric layer DL. Referring to FIG. 14D, for example, the etching process of the dielectric layer DL may be performed in several steps such as a first etching operation, a second etching operation, . . . , etc. in time sequence, and the step cover layer 200 may be formed in any operation, for example, immediately after the first etching operation, immediately after the second etching operation, . . . , etc. of the dielectric layer DL. When the step cover layer 200 is formed immediately after the first etching operation of the dielectric layer DL, the step cover layer 200 may be formed by depositing a material whose composition is sufficiently similar or equivalent to that of the dielectric layer DL.

As illustrated in FIGS. 14A to 14D, when the mask layer MK1 has a stacked structure of the photoresist layer PR and at least one hard mask layer, even when the step cover layer 200 is formed in any operation among the process of exposing the photoresist layer PR, the process of etching the hard mask layer and the process of etching the dielectric layer DL, as the sidewall portion 210 of the step cover layer 200 withstands the etching process to be left, the width or cross-sectional size of the final engraved pattern DLa formed in the dielectric layer DL may be reduced compared to the opening MK1a formed by the process of exposing the photoresist layer PR by the sidewall portion 210 of the step cover layer 200 left during the etching process. Hereinafter, for convenience of explanation, it will be considered that the step cover layer 200 is formed on the patterned mask layer MK1 to expose the dielectric layer DL through the opening MK1a.

Referring to FIGS. 10A to 10J, when the dielectric layer DL is etched through the opening MK1a of the mask layer MK1 and then the mask layer MK1 is removed, as shown in FIG. 10E, a structure having the engraved pattern DLa in the dielectric layer DL may be obtained.

Next, as shown in FIGS. 10F to 10I, the second patterning process is performed to form the engraved pattern DLb for forming a second nanopost NP2 having the width greater than the exposure diffraction limit in the dielectric layer DL.

First, as shown in FIG. 10F, a mask layer MK2 may be formed on the dielectric layer DL in which the engraved pattern DLa is formed. The mask layer MK2 may be a photoresist layer. As another example, the mask layer MK2 may be formed as a stacked structure of at least one hard mask layer and the photoresist layer PR, like the mask layer MK1 described above. As another example, the mask layer MK2 may be formed as at least one hard mask layer. Various modifications of the mask layer MK2 and a material of the hard mask layer may be inferred from the description of the mask layer MK1 described above, and thus, repetitive descriptions thereof are omitted.

Next, as shown in FIG. 10G, an opening MK2a may be formed to correspond to the size, shape, and/or arrangement of the engraved pattern DLb to be formed at a position where the engraved pattern DLb is to be formed, by patterning the mask layer MK2 through a patterning process (e.g., a photoresist layer exposure process, a hard mask layer etching process, or the exposure process and the subsequent etching process). At this time, the width of the opening MK2a formed at the corresponding position may correspond to the width of the engraved pattern DLb in FIG. 9C. In addition, the shape of the opening MK2a may be formed to correspond to the shape of the engraved pattern DLb. For example, when the engraved pattern DLb is circular, the opening MK2a is also formed in a circular shape, and the width of the opening MK2a or the engraved pattern DLb may correspond to the diameter.

Next, as shown in FIG. 10H, a process of etching the dielectric layer DL is performed through the opening MK2a. During the etching process, a portion of the dielectric layer DL exposed through the opening MK2a may be removed to form the engraved pattern DLb. The exposed dielectric layer DL may be removed through, for example, the fluorine-based reactive ion etching process to form the engraved pattern DLb. At this time, a cross-sectional size of the final engraved pattern DLb may correspond to a cross-sectional size of the opening MK2a. Here, when a material layer exists between the opening MK2a and the dielectric layer DL, the existing material layer may be etched in advance for the process of etching the dielectric layer DL through the opening MK2a.

Next, when the mask layer MK2 is removed, a structure having the engraved patterns DLa and DLb in the dielectric layer DL may be obtained, as shown in FIG. 10I.

Next, when the engraved patterns DLa and DLb formed in the dielectric layer DL are filled with a nanostructure material, and an unnecessary upper region is removed through CMP, as shown in FIG. 10J, a single color separating lens layer structure in which the first nanopost NP1 and the second nanopost NP2 are formed in the dielectric layer DL may be obtained. As a result, the color separating lens array 130 in which the first nanopost NP1 and the second nanopost NP2 are disposed in the dielectric layer DL may be formed. The process of forming the engraved pattern DLb in the dielectric layer DL has been described with reference to FIGS. 10F to 10I, but is not limited thereto. The process of forming the engraved pattern DLb in the dielectric layer DL through the second patterning process may correspond to repetition of the process of forming the engraved pattern DLa described with reference to FIGS. 10A to 10E, but the width of at least some of the openings MK2a formed in the mask layer MK2 may be greater than the width of the opening MK1a formed in the mask layer MK1. For example, the above-described step cover layer 200 may be applied even when forming the engraved pattern DLb.

FIGS. 11A to 11K show a manufacturing process of forming a first nanopost NP1 and a second nanopost NP2 through a double patterning process, and exemplarily illustrate a manufacturing process in which a nanostructure material filling operation to form the first nanopost NP1 and a nanostructure material filling operation to form the second nanopost NP2 are separately performed. FIGS. 11A to 11E show a manufacturing process of forming an engraved pattern DLa to form a first nanopost NP1 (FIG. 11F) having a size range that requires consideration of the influence of an exposure diffraction limit, that is, a width close to the exposure diffraction limit, or a width of the exposure diffraction limit or less, and FIGS. 11G to 11J show a manufacturing process of forming an engraved pattern DLb to form a second nanopost NP2 (FIG. 11K) having a size range that does not need to consider the influence of the exposure diffraction limit, that is, a width greater than the exposure diffraction limit.

First, in order to form the engraved pattern DLa for forming the first nanopost NP1 in a dielectric layer DL, the dielectric layer DL is formed on a spacer layer 120, and a first patterning process is performed on the dielectric layer DL as shown in FIGS. 11A to 11E. The first patterning process of FIGS. 11A to 11E is substantially the same as the first patterning process described above with reference to FIGS. 10A to 10E, and thus, repetitive descriptions thereof are omitted. Through the manufacturing process shown in FIGS. 11A to 11E, the engraved pattern DLa may be formed in the dielectric layer DL in a desired size, shape, and/or arrangement.

Next, when the engraved pattern DLa is filled with a nanostructure material, the first nanopost NP1 having the width close to the exposure diffraction limit, or a width of the exposure diffraction limit or less may be formed, as shown in FIG. 11F. To this end, the engraved pattern DLa may be filled with a material having a different refractive index from that of a material of the dielectric layer DL, such as SiON, HfO₂, etc., by using ALD. When the engraved pattern DLa is filled with the nanostructure material, and an unnecessary upper region is removed through CMP, a structure in which the first nanopost NP1 is formed in the dielectric layer DL may be obtained. Here, the nanostructure material for forming the first nanopost NP1 may be filled after removing the mask layer MK1, but embodiments not limited thereto. For example, the mask layer MK1 may be removed after the nanostructure material for forming the first nanopost NP1 is filled.

Next, as shown in FIGS. 11G to 11J, a second patterning process is performed to form the engraved pattern DLb for forming the second nanopost NP2 having the width greater than the exposure diffraction limit in the dielectric layer DL.

First, as shown in FIG. 11G, the mask layer MK2 may be formed on the dielectric layer DL on which the first nanopost NP1 is formed. The mask layer MK2 may be a photoresist layer. As another example, the mask layer MK2 may be formed as a stacked structure of at least one hard mask layer and the photoresist layer PR, like the mask layer MK1 described above As another example, the mask layer MK2 may be formed as at least one hard mask layer.

Next, as shown in FIG. 11H, the opening MK2a may be formed to correspond to the size, shape, and/or arrangement of the engraved pattern DLb to be formed at a position where the engraved pattern DLb is to be formed, by patterning the mask layer MK2 through a patterning process (e.g., a photoresist layer exposure process, a hard mask layer etching process, or the exposure process and the subsequent etching process). At this time, the width of the opening MK2a formed at the corresponding position may correspond to the width of the engraved pattern DLb in FIG. 9C. In addition, the shape of the opening MK2a may be formed to correspond to the shape of the engraved pattern DLb. For example, when the engraved pattern DLb is circular, the opening MK2a is also formed in a circular shape, and the width of the opening MK2a or the engraved pattern DLb may correspond to a diameter.

Next, as shown in FIG. 11I, a process of etching the dielectric layer DL is performed through the opening MK2a. During the etching process, a portion of the dielectric layer DL exposed through the opening MK2a may be removed to form the engraved pattern DLb. The exposed dielectric layer DL may be removed through, for example, a fluorine-based reactive ion etching process to form the engraved pattern DLb. At this time, a cross-sectional size of the final engraved pattern DLb may correspond to a cross-sectional size of the opening MK2a.

Next, when the mask layer MK2 is removed, a structure having the engraved pattern DLb in the dielectric layer DL may be obtained, as shown in FIG. 11J.

Next, the second nanopost NP2 may be formed by filling the engraved pattern DLb formed in the dielectric layer DL with a nanostructure material. To this end, the engraved pattern DLb may be filled with a material having a different refractive index from that of a material of the dielectric layer DL, such as TiO₂, etc., by using ALD. As described above, the nanostructure material for forming the second nanopost NP2 may be filled after removing the mask layer MK2, but embodiments not limited thereto. For example, the mask layer MK2 may be removed after the nanostructure material for forming the nanopost NP2 is filled.

After the second nanopost NP2 is formed, when an unnecessary upper region is removed through CMP, as shown in FIG. 11K, a single color separating lens layer structure in which the first nanopost NP1 and the second nanopost NP2 are formed in the dielectric layer DL may be obtained. As a result, a color separating lens layer of the color separating lens array 130 in which the first nanopost NP1 and the second nanopost NP2 are disposed in the dielectric layer DL may be formed.

As shown in FIGS. 11A to 11K, when a process of forming the first nanopost NP1 by filling the engraved pattern DLa with a nanostructure material, and a process of forming the second nanopost NP2 by filling the engraved pattern DLb with a nanostructure material are separately performed, the first nanopost NP1 and the second nanopost NP2 may include different nanostructure materials or the same nanostructure material. For example, the first nanopost NP1 may include SiON, HfO₂, etc., and the second nanopost NP2 may include TiO₂, etc. In addition, the first nanopost NP1 and the second nanopost NP2 may include the same material, such as TiO₂, SiON, HfO₂, etc. In addition, one of the first nanopost NP1 and the second nanopost NP2 may include a nanostructure material such as TiO₂, SiON, HfO₂, etc., and the other may be left as an empty space.

FIGS. 10A to 10J and 11A to 11K show that one engraved pattern DLa and one engraved pattern DLb are each formed, and one first nanopost NP1 and one second nanopost NP2 are formed by filling the engraved patterns DLa and DLb with a nanostructure material, but this is only an example and is not limited thereto. The sizes, shapes, and/or arrangements of the engraved pattern DLa formed through the first patterning process and the engraved pattern DLb formed through the second patterning process may vary depending on the design of the color separating lens array 130 of the pixel array 1100 of the image sensor 1000 according to the example embodiment. For example, when the color separating lens array 130 has the sizes, shapes, distances, and/or arrangements of the first nanopost NP1 and the second nanopost NP2 as described above with reference to FIG. 5B, the engraved patterns DLa and DLb may be formed in the corresponding sizes, shapes, distances and/or arrangements.

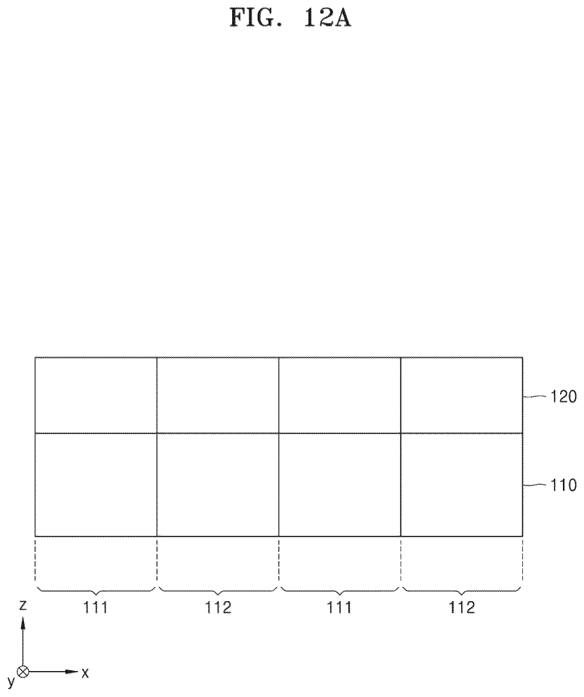

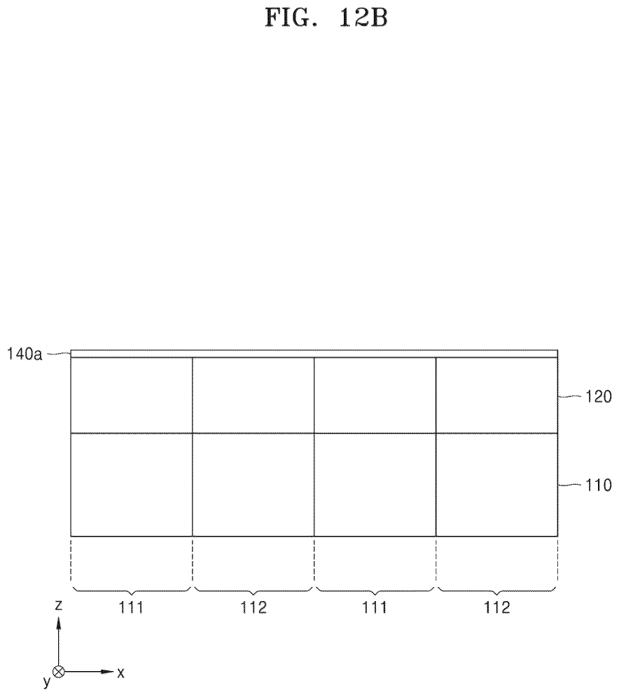

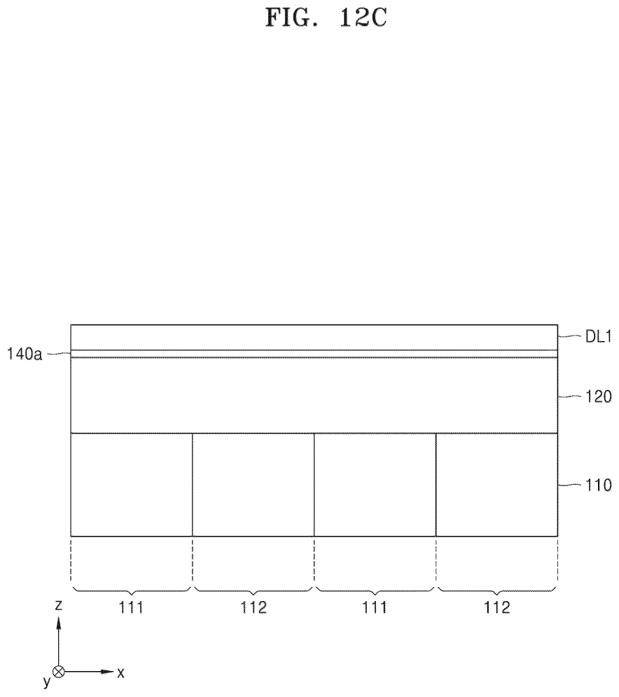

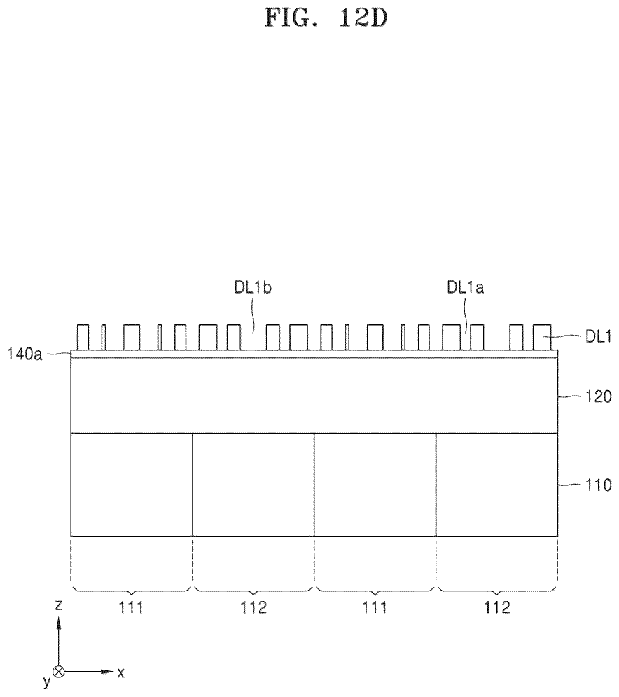

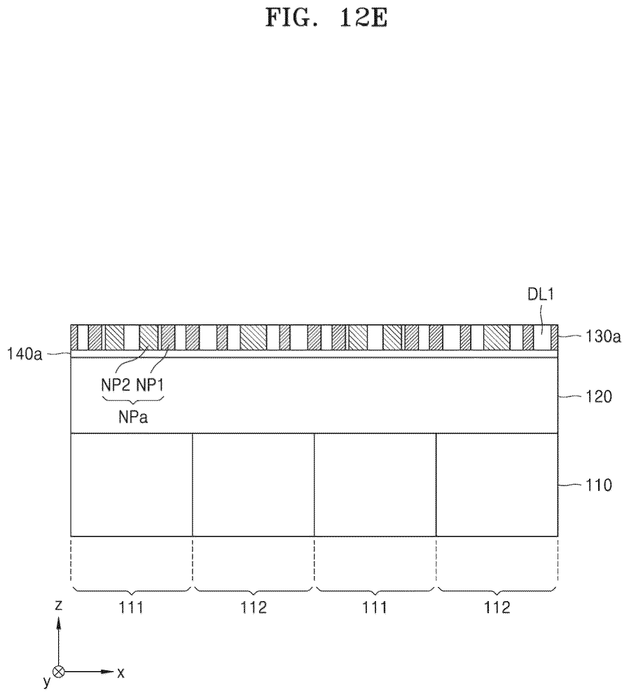

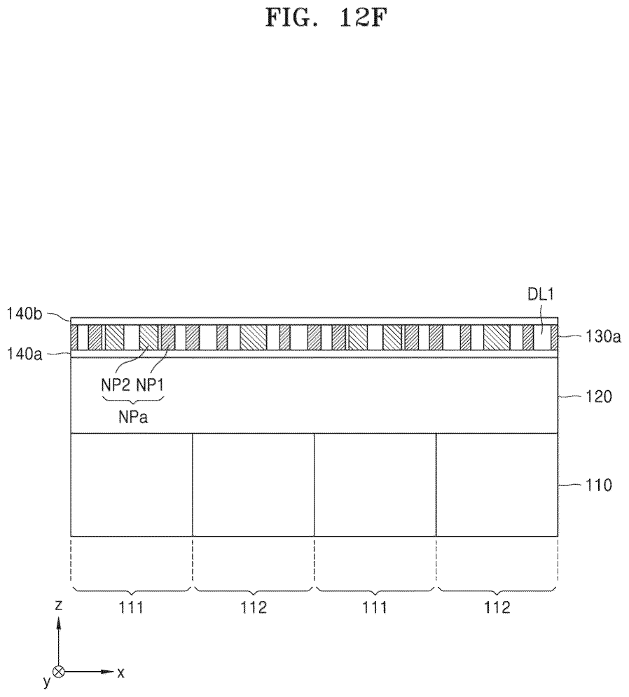

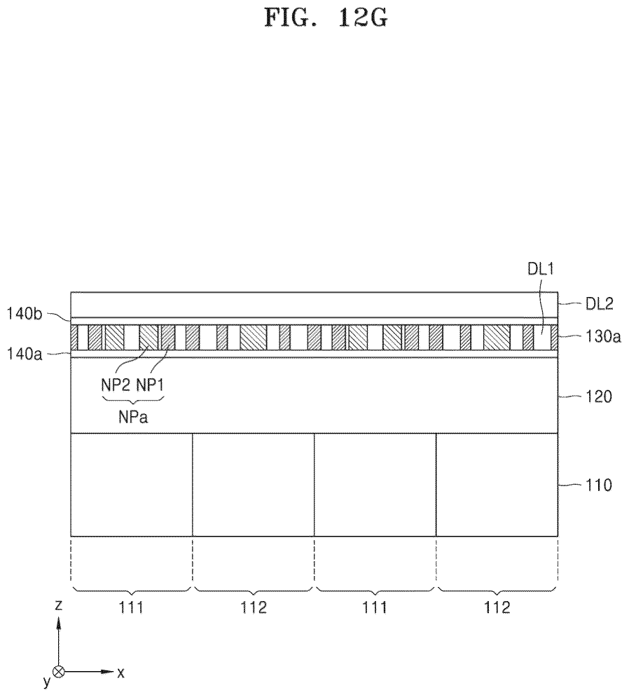

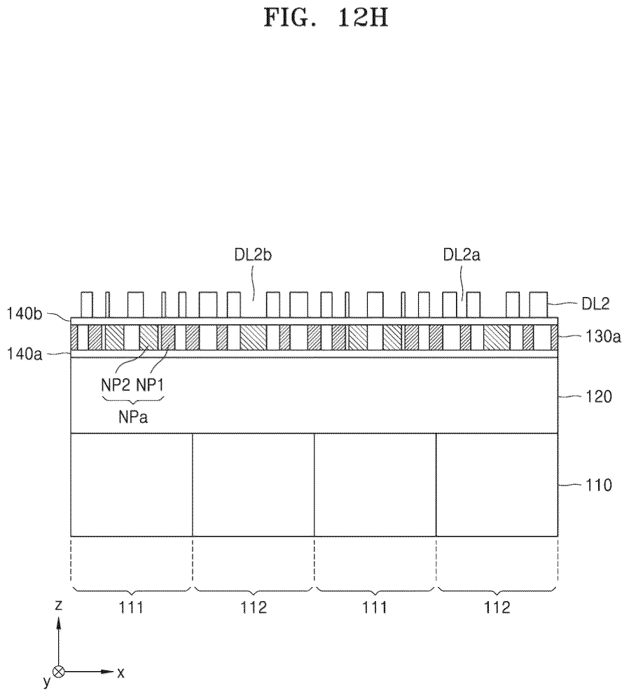

FIGS. 12A to 12I are diagrams for explaining a method of manufacturing the pixel array 1100 of the image sensor 1000 according to an example embodiment of FIGS. 8A and 8B.

First, as shown in FIG. 12A, a spacer 120 layer is formed on a sensor substrate 110. The spacer layer 120 may be, for example, a SiO₂ layer, and may be formed using various physical or chemical forming methods, such as thermal oxidation.

Next, as shown in FIG. 12B, a first etch stop layer 140a is formed on the spacer layer 120. The first etch stop layer 140a is a layer to prevent the spacer layer 120 from being damaged during a process of forming the first color separating lens layer 130a, and may be a layer made of a material that is not etched by a material that may selectively etch a first dielectric layer DL1, that is, a material that may be used to etch the first dielectric layer DL1, for example, HfO₂. A HfO₂ layer may be formed by a physical or chemical forming method, such as PVD, CVD, PE-CVD, ALD, etc. The first etch stop layer 140a may be formed over the entire area of the spacer layer 120. The first etch stop layer 140a may be formed to have a thickness by which a lower layer protection function may be performed without impairing an optical characteristics of the color separating lens array 130 For example, the first etch stop layer 140a may be formed to have the thickness of, for example, about 3 nm to about 30 nm or about 5 nm to about 15 nm.

Next, as shown in FIGS. 12C to 12E, a first color separating lens layer 130a may be formed through a double patterning process.

To this end, first, as shown in FIG. 12C, the first dielectric layer DL1 is formed on the first etch stop layer 140a. The first dielectric layer DL1 may be a SiO₂ layer. As another example, the first dielectric layer DL1 may be formed on the spacer layer 120 without the first etch stop layer 140a. In this case, the operation in FIG. 12B may be omitted, and FIGS. 12C to 12I may be changed to a structure without the first etch stop layer 140a. Here, an example of forming the first etch stop layer 140a on the spacer layer 120 and forming the first dielectric layer DL1 on the first etch stop layer 140a is described.

Next, as shown in FIG. 12D, engraved patterns DL1a and DL1b are formed in the first dielectric layer DL1 through a patterning process. The engraved patterns DL1a and DL1b may be formed by forming the mask layer (MK1 in FIG. 10A) on the first dielectric layer DL1, patterning the mask layer through the patterning process including an exposure process (an exposure process or an exposure process and a subsequent etching process), and then removing the exposed first dielectric layer DL1 through an etching process, for example, a fluorine-based reactive ion etching process. The engraved patterns DL1a and DL1b may be formed using different patterning processes. For example, the engraved pattern DL1a may be formed through a first patterning process, and the engraved pattern DL1b may be formed through a second patterning process. In this way, the engraved patterns DL1a and DL1b may be formed through the double patterning process.

The engraved pattern DL1a is for forming first nanoposts NP1 of the first color separating lens layer 130a, and to this end, may be formed to have a relatively small width, for example, a width close to an exposure diffraction limit, or a width of the exposure diffraction limit or less. The engraved pattern DL1b is for forming second nanoposts NP2 of the first color separating lens layer 130a, and to this end, may be formed to have a relatively great width, for example, a width greater than the exposure diffraction limit. As in the manufacturing process described above with reference to FIGS. 10A to 10K, the engraved pattern DL1a may be formed during the first patterning process, and the engraved pattern DL1b may be formed during the second patterning process.

Next, as shown in FIG. 12E, nanoposts NPa of the first color separating lens layer 130a may be formed by filling the engraved patterns DL1a and DL1b formed in the first dielectric layer DL1 with a nanostructure material. To this end, for example, the first nanoposts NP1 and the second nanoposts NP2 may form an arrangement of the nanoposts NPa of the first color separating lens layer 130a arranged in a desired shape, size, and/or arrangement, as shown in FIG. 5B, by filling the engraved patterns DL1a and DL1b with a material having a different refractive index from that of the material of the first dielectric layer DL1, such as TiO₂, SiON, HfO₂, etc., by using ALD. A material deposited at an upper portion of the first dielectric layer DL1 may be removed through a CMP process after deposition to form the first color separating lens layer 130a of the color separating lens array 130.

FIGS. 12D and 12E exemplarily illustrate that the first nanoposts NP1 and the second nanoposts NP2 of the first color separating lens layer 130a are formed by forming the engraved patterns DL1a and DL1b through the double patterning process and then filling the engraved patterns DL1a and DL1b with a nanostructure material in the same operation simultaneously, as described above with reference to FIGS. 10A to 10J, but embodiments not limited thereto. For example, similar to the manufacturing process of forming the first nanopost NP1 and the second nanopost NP2 through the double patterning process described above with reference to FIGS. 11A to 11K, the first nanopost NP1 of the first color separating lens layer 130a may be formed by forming the engraved pattern DL1a through the first patterning process and filling the engraved pattern DL1a with a nanostructure material, and then, the second nanopost NP2 of the first color separating lens layer 130a may be formed by forming the engraved pattern DL1b through the second patterning process and filling the engraved pattern DL1b with a nanostructure material. For example, the nanostructure material filling operation to form the first nanopost NP1 of the first color separating lens layer 130a and the nanostructure material filling operation to form the second nanopost NP2 of the first color separating lens layer 130a may be separately performed.

In this way, the first color separating lens layer 130a may be formed through the double patterning process, and then a second etch stop layer 140b may be formed on the first color separating lens layer 130a, as shown in FIG. 12F.

The second etch stop layer 140b is a layer to prevent the first color separating lens layer 130a from being damaged during a process of forming a second color separating lens layer 130b. Like the first etch stop layer 140a, the second etch stop layer 140b may be a layer made of a material that is not etched by a material that may selectively etch a second dielectric layer DL2, that is, a material that may be used to etch the second dielectric layer DL2, for example, HfO₂. A HfO₂ layer may be formed by a physical or chemical forming method, such as PVD, CVD, PE-CVD, ALD, etc. The second etch stop layer 140b may be formed over the entire area of the first color separating lens layer 130a. The second etch stop layer 140b may be formed to have a thickness by which a lower layer protection function may be performed without impairing the optical characteristics of the first color separating lens layer 130a and a second color separating lens layer 130b of the color separating lens array 130. For example, the second etch stop layer 140b may be formed to have the thickness of, for example, about 3 nm to about 30 nm or about 5 nm to about 15 nm.

Next, as shown in FIGS. 12G to 12I, the second color separating lens layer 130b may be formed through the double patterning process. However, nanoposts NPb of the second color separating lens layer 130b may be shifted toward the center C of the color separating lens array 130 compared to the nanopost NPa of the first color separating lens layer 130a.

To this end, first, as shown in FIG. 12G, a second dielectric layer DL2 may be formed on the second etch stop layer 140b. The second dielectric layer DL2 may be a SiO₂ layer. As another example, the second dielectric layer DL2 may be formed on the first color separating lens layer 130a without the second etch stop layer 140b. In this case, the operation of FIG. 12F may be omitted, and FIGS. 12G to 12I may be changed to a structure without the second etch stop layer 140b. Here, an example of forming the second etch stop layer 140b on the first color separating lens layer 130a and forming the second dielectric layer DL2 on the second etch stop layer 140b is described.

Next, as shown in FIG. 12H, engraved patterns DL2a and DL2b are formed in the second dielectric layer DL2 through the patterning process. The engraved patterns DL2a and DL2b may be formed by forming a mask layer (corresponding to MK1 in FIG. 10A) on the second dielectric layer DL2, patterning the mask layer through the patterning process including an exposure process (an exposure process or an exposure process and a subsequent etching process), and then removing the exposed second dielectric layer DL2 through an etching process, for example, the fluorine-based reactive ion etching process. The engraved pattern DL2a may be formed through the first patterning process, and the engraved pattern DL2b may be formed through the second patterning process. In this way, the engraved patterns DL2a and DL2b may be formed through the double patterning process.

The engraved pattern DL2a is for forming first nanoposts NP1 of the second color separating lens layer 130b, and to this end, may be formed to have a relatively small width, for example, a width close to an exposure diffraction limit, or a width of the exposure diffraction limit or less. The engraved pattern DL2b is for forming second nanoposts NP2 of the second color separating lens layer 130b, and to this end, may be formed to have a relatively great width, for example, a width greater than the exposure diffraction limit. As in the manufacturing process described above with reference to FIGS. 10A to 10J and 11A to 11K, the engraved pattern DL2a may be formed during the first patterning process, and the engraved pattern DL2b may be formed during the second patterning process. At this time, in order to more shift, for example, the nanoposts NPb of the second color separating lens layer 130b toward the center C of the color separating lens array 130 than the nanopost NPa of the first color separating lens layer 130a, as described above with reference to FIGS. 8A and 8B, the engraved patterns DL2a and DL2b may be formed to be shifted toward the center C of the color separating lens array 130, compared to the engraved patterns DL1a and DL1b formed in the first dielectric layer DL1.

Next, as shown in FIG. 12I, the nanoposts NPb of the second color separating lens layer 130b may be formed by filling the engraved patterns DL2a and DL2b formed in the second dielectric layer DL2 with a nanostructure material. To this end, for example, the first nanoposts NP1 and the second nanoposts NP2, may form an arrangement of the nanoposts NPb of the second color separating lens layer 130b arranged in a desired shape, size, and/or arrangement, as shown in FIG. 5B, by filling the engraved patterns DL2a and DL2b with a material having a different refractive index from that of the material of the second dielectric layer DL2, such as TiO₂, SiON, HfO₂, etc., by using ALD. At this time, the first nanoposts NP1 and the second nanoposts NP2 of the second color separating lens layer 130b may be formed to be more shifted toward the center C of the color separating lens array 130 than the first nanoposts NP1 and the second nanoposts NP2 of the first color separating lens layer 130a. A material deposited at an upper portion of the second dielectric layer DL2 may be removed through a CMP process after deposition to form the second color separating lens layer 130b of the color separating lens array 130.

FIGS. 12H and 12I exemplarily illustrate that first nanoposts NP1 and second nanopost NP2 of the second color separating lens layer 130b are formed by forming engraved patterns DL2a and DL2b through the double patterning process and then filling the engraved patterns DL2a and DL2b with a nanostructure material in the same operation simultaneously, as described above with reference to FIGS. 10A to 10J, but embodiments not limited thereto. For example, similar to the manufacturing process of forming the first nanopost NP1 and the second nanopost NP2 through the double patterning process described above with reference to FIGS. 11A to 11K, the first nanopost NP1 of the second color separating lens layer 130b may be formed by forming the engraved pattern DL2a through the first patterning process and filling the engraved pattern DL2a with a nanostructure material, and then, the second nanopost NP2 of the second color separating lens layer 130b may be formed by forming the engraved pattern DL2b through the second patterning process and filling the engraved pattern DL2b with a nanostructure material. For example, a nanostructure material filling operation to form the first nanopost NP1 of the second color separating lens layer 130b and a nanostructure material filling operation to form the second nanopost NP2 of the second color separating lens layer 130b may be separately performed.

As described above, according to the image sensor 1000 and a method of manufacturing the image sensor 1000 according to the example embodiment, the first patterning process of forming an engraved pattern for forming the plurality of first nanoposts NP1 including a nanopost with a width of an exposure diffraction limit or less and having one or more widths in a size range that requires consideration of the influence of the exposure diffraction limit is performed, and then, and then the second patterning process of forming an engraved pattern for forming the plurality of second nanoposts NP2 each having a width in a size range that does not need to consider the influence of the exposure diffraction limit, that is, greater than the exposure diffraction limit, is performed. Thus, the dispersion of nanoposts to be formed may be reduced.

In other words, according to the manufacturing method, there are a size limit of an implementable structure and a lower limit of a tolerance. For example, in a problem of digging a small-sized hole deeply, a size is firstly determined by the diffraction limit ˜λ/2NA guaranteed in the exposure process, and when transferring small-sized holes in process of etching a mask layer of a high aspect ratio, the size dispersion may increase. In addition, as a high NA (numerical opening) is used to form a small-sized hole, a depth of focus (DOF) becomes shorter. When a photoresist layer forming a mask layer is not sufficiently flat, small-sized holes become smaller and large-sized holes become larger due to an off-focus effect, resulting in increased pattern skew increase during the exposure process and a photoresist is exposed unevenly, and thus, the dispersion may further increase. This dispersion causes fixed optical noise and increases the optical noise of an image sensor, which may be a factor in deteriorating performance.

According to the image sensor 1000 and a method of manufacturing the image sensor 1000 according to the embodiment, a patterning process for forming the plurality of first nanoposts NP1 including a nanopost with a width of the exposure diffraction limit or less and having one or more widths, and a patterning process for forming the plurality of second nanoposts NP2 each having a width greater than the exposure diffraction limit are separately performed, the dispersion of nanoposts to be formed may be reduced. As a result, even small-sized nanoposts may be implemented, making it possible to design a wide degree of freedom, and thus, enabling detailed scattering control and improving performance.

In addition, according to the image sensor 1000 and the method of manufacturing the image sensor 1000 according to the embodiment, when a large pattern and a small pattern are simultaneously etched, problems caused by a loading effect of different etching rates depending on pattern sizes may be overcome. For example, when a large pattern and a small pattern are simultaneously etched, an etch stop layer needs to endure more etching time due to the loading effect, which requires adoption of a thicker etch stop layer. This etch stop layer may not be too thick to minimize optical side effects. According to the image sensor 1000 and the method of manufacturing the image sensor 1000 according to the embodiment, a patterning process for forming the plurality of first nanoposts NP1 and a patterning process for forming the plurality of second nanoposts NP2 are separately performed, and thus, the thickness of the etch stop layer may be selected within an appropriate range.

In addition, according to the image sensor 1000 and the method of manufacturing the image sensor 1000 according to the embodiment, by designing the first patterning process and the second patterning process to prevent patterns that are too close from being etched at once, it is possible overcoming a problem in that when the patterns that are too close are etched at once, a width of a mask layer portion therebetween is small, thereby etched in three-dimensional and increasing etching rate. In addition, according to the image sensor 1000 and the method of manufacturing the image sensor 1000 according to the embodiment, even when vertical profiles are different or sizes differently change, the first patterning process and the second patterning process are appropriately formed, thereby reducing the burden of the etching process.

Meanwhile, it has been described and illustrated above that the image sensor 1000 is formed by applying the first patterning process to form the plurality of first nanoposts NP1 and the second patterning process to form the plurality of second nanoposts NP2, but embodiments not limited thereto. In other words, the patterning process is not limited to two times and may be divided into three or more times. For example, according to the image sensor 1000 and the method of manufacturing the image sensor 1000 according to the embodiment, through two or more patterning processes and one or more nanostructure material filling process, a color separating lens layer of the color separating lens array 130 including the first nanoposts NP1 and the second nanoposts NP2 may be formed.

In addition, it has been described and illustrated above that the first patterning process and the second patterning process are applied considering only the size of a nanopost to be formed, but embodiments not limited thereto. For example, considering the allowable range of an etching rate difference depending on the pattern size, some of the first nanoposts NP1 may be formed by applying the second patterning process, and some of the second nanoposts NP2 may be formed by applying the first patterning process. In this case, different patterning processes may be applied to nanoposts that have a relatively small size difference and are too close, and thus it is possible suppressing a dispersion occurred due to that when patterns that are too close are etched at once, a width of a mask layer portion therebetween is small, thereby etched three-dimensionally and increasing etching rate.

In addition, an example of forming the color separating lens layer including the first nanopost NP1 and the second nanopost NP2 through two or more patterning processes and one or more nanostructure material filling process has been described and illustrated, but embodiments not limited thereto. For example, a variety of image sensors that require a nanostructure of an exposure diffraction limit or less may be applied. A variety of image sensors, such as an image sensor in which individual pixels with a small width of the diffraction limit or less distinguish and detect light in a plurality of types of wavelength bands, an image sensor with a high color purity by employing an anti-reflection layer including a nanostructure, etc. may be applied, a multi-color sensor or a hyperspectral sensor may be used, or as a 3D image sensor that provides both a color image and a depth image may be used. The image sensor 1000 according to an embodiment may form a camera module with a module lens of various performances and may be used in various electronic devices.

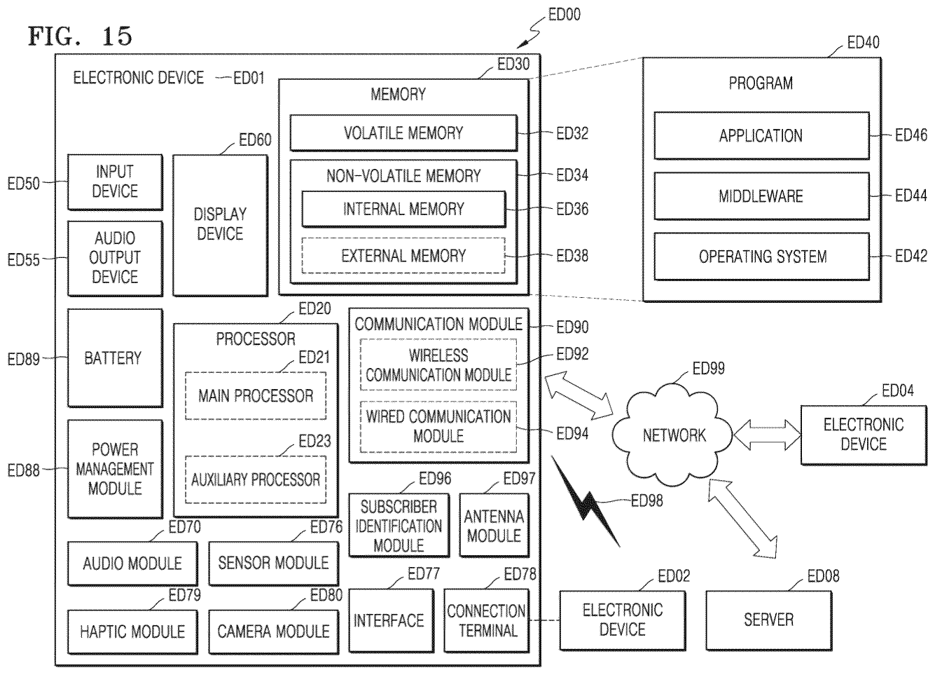

FIG. 15 is a block diagram of an example of an electronic device ED01 including the image sensor 1000. Referring to FIG. 15, in a network environment ED00, the electronic device ED01 may communicate with another electronic device ED02 via a first network ED98 (short-range wireless communication network, etc.), or may communicate with another electronic device ED04 and/or a server ED08 via a second network ED99 (long-range wireless communication network, etc.) The electronic device ED01 may communicate with the electronic device ED04 via the server ED08. The electronic device ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic device ED01, some (display device ED60, etc.) of constituent elements may be omitted or another constituent element may be added. Some of the constituent elements may be implemented as one integrated circuit. For example, the sensor module ED76 (a fingerprint sensor, an iris sensor, an illuminance sensor, etc.) may be implemented by being embedded in the display device ED60 (display, etc.)

The processor ED20 may control one or a plurality of other constituent elements (hardware and software constituent elements, and the like) of the electronic device ED01 connected to the processor ED20 by executing software (a program ED40, and the like), and perform various data processing or calculations. As part of the data processing or calculations, the processor ED20 may load, in a volatile memory ED32, commands and/or data received from other constituent elements (the sensor module ED76, the communication module ED90, and the like), process the command and/or data stored in the volatile memory ED32, and store result data in a non-volatile memory ED34. The processor ED20 may include a main processor ED21 (a central processing unit, an application processor, and the like) and an auxiliary processor ED23 (a graphics processing unit, an image signal processor, a sensor hub processor, a communication processor, and the like) that is operable independently of or together with the main processor ED21. The auxiliary processor ED23 may use less power than the main processor ED21, and may perform a specified function.

Instead of the main processor ED21 when the main processor ED21 is in an inactive state (sleep state), or with the main processor ED21 when the main processor ED21 is in an active state (application execution state), the auxiliary processor ED23 may control functions and/or states related to some constituent elements (the display device ED60, the sensor module ED76, the communication module ED90, and the like) of the constituent elements of the electronic device ED01. The auxiliary processor ED23 (an image signal processor, a communication processor, etc.) may be implemented as a part of another constituent element (the camera module ED80, the communication module ED90, etc.) that is functionally related thereto.

The memory ED30 may store various data required by the constituent elements (the processor ED20, the sensor module ED76, etc.) of the electronic device ED01. The data may include, for example, software (the program ED40, and the like) and input data and/or output data about commands related thereto. The memory ED30 may include the volatile memory ED32 and/or the non-volatile memory ED34. The nonvolatile memory ED34 may include an internal memory ED36 fixedly mounted in the electronic device ED01 and a detachable external memory ED38.

The program ED40 may be stored as software in the memory ED30, and may include an operation system ED42, middleware ED44, and/or an application ED46.

The input device ED50 may receive commands and/or data to be used for constituent elements (the processor ED20, etc.) of the electronic device ED01, from outside (a user, etc.) of the electronic device ED01. The input device ED50 may include a microphone, a mouse, a keyboard, and/or a digital pen (stylus pen, etc.).

The audio output device ED55 may output an audio signal to outside of the electronic device ED01. The audio output device ED55 may include a speaker and/or a receiver. The speaker may be used for a general purpose such as multimedia playback or recording playback, and the receiver may be used to receive incoming calls. The receiver may implemented by being coupled as a part of the speaker or by an independent separate device.

The display device ED60 may provide visually information to outside of the electronic device ED01. The display device ED60 may include a display, a hologram device, or a projector, and a control circuit for controlling the corresponding device. The display device ED60 may include a touch circuitry set to sense a touch, and/or a sensor circuit (a pressure sensor, etc.) that is set to measure a strength of a force generated by the touch.

The audio module ED70 may convert sound into an electrical signal or vice versa. The audio module ED 70 may acquire sound through the input device ED50, or may output sound via the audio output device ED55 and/or a speaker and/or a headphone of another electronic device (electronic device ED02, etc.) connected to the electronic device ED01 in a wired or wireless manner.

The sensor module ED76 may sense an operating state (power, temperature, etc.) of the electronic device ED01, or an outer environmental state (a user state, etc.), and may generate an electrical signal and/or a data value corresponding to a sensed state. The sensor module ED76 may include a gesture sensor, a gyro-sensor, a barometric pressure sensor, a magnetic sensor, an acceleration sensor, a grip sensor, a proximity sensor, a color sensor, an IR sensor, a biometric sensor, a temperature sensor, a humidity sensor, and/or an illuminance sensor.

The interface ED77 may support one or a plurality of designated protocols that may be used in order for the electronic device ED01 to another electronic device (the electronic device ED02, etc.) in a wired or wireless manner. The interface ED77 may include a high-definition multimedia interface (HDMI), a universal serial bus (USB) interface, an SD card interface, and/or an audio interface.

A connection terminal ED78 may include a connector by which the electronic device ED01 may be physically connected to another electronic device (the electronic device ED02, etc.). The connection terminal ED78 may include an HDMI connector, a USB connector, an SD card connector, and/or an audio connector (a headphone connector, etc.).

The haptic module ED79 may convert an electrical signal into a mechanical stimulation (a vibration, a movement, etc.) or an electric stimulation that are perceivable by a user through a tactile or motion sensation. The haptic module ED79 may include a motor, a piezoelectric device, and/or an electric stimulus device.

The camera module ED80 may capture a still image and a video. The camera module ED80 may include a lens assembly including one or a plurality of lenses, the image sensor 1000 of FIG. 1, image signal processors, and/or flashes. The lens assembly included in the camera module ED80 may collect light emitted from an object for image capturing.

The power management module ED88 may manage the power supplied to the electronic device ED01. The power management module ED88 may be implemented as a part of a power management integrated circuit (PMIC).

The battery ED89 may supply electric power to components of the electronic device ED01. The battery ED89 may include a non-rechargeable primary cell, a rechargeable secondary cell, and/or a fuel cell.

The communication module ED90 may establish a wired communication channel and/or a wireless communication channel between the electronic device ED01 and another electronic device (the electronic device ED02, the electronic device ED04, server ED08, etc.), and support a communication through an established communication channel. The communication module ED90 may be operated independently from the processor ED20 (the application processor, etc.), and may include one or a plurality of communication processors that support a wired communication and/or a wireless communication. The communication module ED90 may include a wireless communication module ED92 (a cellular communication module, a short-range wireless communication module, a global navigation satellite system (GNSS) communication module) and/or a wired communication module ED94 (a local area network (LAN) communication module, a power line communication module, etc.). From among the above communication modules, a corresponding communication module may communicate with another electronic device via the first network ED98 (a short-range communication network such as Bluetooth, WiFi Direct, or infrared data association (IrDA)) or the second network ED99 (a long-range communication network such as a cellular network, the Internet, or a computer network (LAN, WAN, etc.)). Such above various kinds of communication modules may be integrated into one constituent element (a single chip, etc.) or may be implemented as a plurality of separate constituent elements (a plurality of chips). The wireless communication module ED92 may identify and authenticate the electronic device ED01 in a communication network such as the first network ED98 and/or the second network ED99 by using subscriber information (an international mobile subscriber identifier (IMSI), etc.) stored in the subscriber identification module ED96.

The antenna module ED97 may transmit a signal and/or power to outside (another electronic device, etc.) or receive a signal and/or power from the outside. An antenna may include a radiator formed as a conductive pattern formed on a substrate (PCB, etc.). The antenna module ED97 may include one or a plurality of antennas. When the antenna module ED97 includes a plurality of antennas, from among the plurality of antennas, an antenna that is suitable for the communication type used in the communication network such as the first network ED98 and/or the second network ED99 may be selected by the communication module ED90. The signal and/or the power may be transmitted or received between the communication module ED90 and another electronic device via the selected antenna. Another component (an RFIC, etc.) other than the antenna may be included as a part of the antenna module ED97.

Some of the constituent elements may be connected to one another via the communication method between the peripheral devices (a bus, general purpose input and output (GPIO), a serial peripheral interface (SPI), a mobile industry processor interface (MIPI), etc.) and may mutually exchange signals (commands, data, etc.)

The command or data may be transmitted or received between the electronic device ED01 and the external electronic device ED04 via the server ED08 connected to the second network ED99. Other electronic devices ED02 and ED04 may be a device that is the same as or different kinds from the electronic device ED01. All or some of the operations executed in the electronic device ED01 may be executed in one or a plurality of devices among the other electronic devices ED02, ED04, and ED08. For example, when the electronic device ED01 has to perform a certain function or service, the electronic device ED01 may request one or a plurality of other electronic devices to perform some or wholed function or service, instead of executing the function or service by itself. One or a plurality of other electronic devices receiving the request may execute an additional function or service related to the request and may transfer a result of the execution to the electronic device ED01. To this end, cloud computing, distributed computing, and/or client-server computing technology may be used.

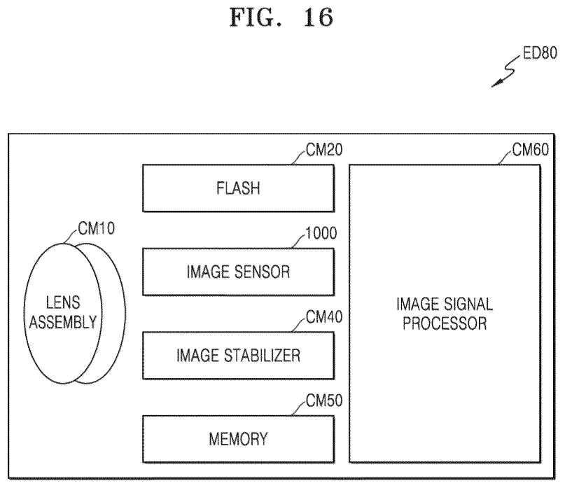

FIG. 16 is a block diagram illustrating an example of the camera module ED80 of FIG. 15.

Referring to FIG. 16, the camera module ED80 may include a lens assembly CM10, a flash CM20, the image sensor 1000 (of FIG. 1), an image stabilizer CM40, a memory CM50 (a buffer memory, etc.), and/or an image signal processor CM60. The lens assembly CM10 may collect light emitted from an object for image capturing. The camera module ED80 may include a plurality of lens assemblies CM10, and in this case, the camera module ED80 may include a dual camera module, a 360-degree camera, or a spherical camera. Some of the plurality of lens assemblies CM10 may have the same lens properties (a viewing angle, a focal length, auto-focus, F number, optical zoom, etc.) or different lens properties. The lens assembly CM10 may include a wide-angle lens or a telephoto lens.

The flash CM20 may emit light that is used to strengthen the light emitted or reflected from the object. The flash CM20 may include one or a plurality of light-emitting diodes (a red-green-blue (RGB)) LED, a white LED, an infrared LED, an ultraviolet LED, etc.), and/or a Xenon lamp. The image sensor 1000 may be the image sensor described above with reference to FIG. 1, and converts the light emitted or reflected from the object and transmitted through the lens assembly CM10 into an electrical signal to obtain an image corresponding to the object. The image sensor 1000 may include one or a plurality of sensors selected from image sensors having different properties, such as an RGB sensor, a black and white (BW) sensor, an IR sensor, or a UV sensor. Each of sensors included in the image sensor 1000 may be implemented as a CCD image sensor or a CMOS image sensor.

The image stabilizer CM40, in response to a movement of the camera module ED80 or an electronic device CM01 including the camera module ED80, may move one or a plurality of lenses included in the lens assembly CM10 or the image sensor 1000 in a certain direction or may control the operating characteristics of the image sensor 1000 (adjusting of a read-out timing, etc.) in order to compensate for a negative influence of the movement. The image stabilizer CM40 may sense the movement of the camera module ED80 or the electronic device ED01 by using a gyro sensor or an acceleration sensor disposed in or out of the camera module ED80. The image stabilizer CM40 may be implemented as an optical type.

The memory CM50 may store some or entire data of an image obtained through the image sensor 1000 for a subsequent image processing operation. For example, when a plurality of images are acquired at a high speed, the acquired original data (Bayer-patterned data, high-resolution data, etc.) may be stored in the memory CM50, and a low-resolution image is only displayed, and then original data of a selected image (user selection, etc.) may be transmitted to the image signal processor CM60. The memory CM50 may be incorporated into the memory ED30 of the electronic device ED01, or configured to be independently operated separate memory.

The image signal processor CM60 may perform image processing on the image obtained through the image sensor 1000 or the image data stored in the memory CM50. The image processings may include depth map generation, three-dimensional modeling, panorama generation, extraction of feature point, image synthesis, and/or image compensation (noise reduction, resolution adjustment, brightness adjustment, blurring, sharpening, softening, etc.). The image signal processor CM60 may perform control (exposure time control, read-out timing control, etc.) of constituent elements (the image sensor 1000, etc.) included in the camera module ED80. The image processed by the image signal processor CM60 may be stored again in the memory CM50 for additional processing, or may be provided to an external constituent element of the camera module ED80 (e.g., the memory ED30, the display device ED60, the electronic device ED02, the electronic device ED04, the server ED08, etc.). The image signal processor CM60 may be incorporated into the processor ED20, or may be configured to be a separate processor operated independently of the processor ED20. When the image signal processor CM60 is configured as a separate processor from the processor ED20, the image processed by the image signal processor CM60 may undergo through an additional image processing by the processor ED20 and then may be displayed on the display device ED60.

Also, the image signal processor CM60 may receive at least two light sensing signals independently in each pixel of the image sensor 1000, and may generate an auto-focusing signal from a difference between the at least light sensing signals. The image signal processor CM60 may control the lens assembly CM10 so that the focus of the lens assembly CM10 may be accurately corresponded on the surface of the image sensor 1000 based on the auto-focusing signal.

The electronic device ED01 may include a plurality of camera modules ED80 having different properties or functions. This camera module may also include configurations similar to those of the camera module ED80 of FIG. 16, and the image sensor included in this camera module may be implemented as a CCD sensor and/or a CMOS sensor and may include one or a plurality of sensors selected from image sensors having different properties, such as an RGB sensor, a black and white (BW) sensor, an IR sensor, or a UV sensor. In this case, one of the plurality of camera modules ED80 may include a wide-angle camera and another camera module ED80 may include a telephoto camera. Similarly, one of the plurality of camera modules ED80 may include a front side camera and another camera module ED80 may include a rear side camera.

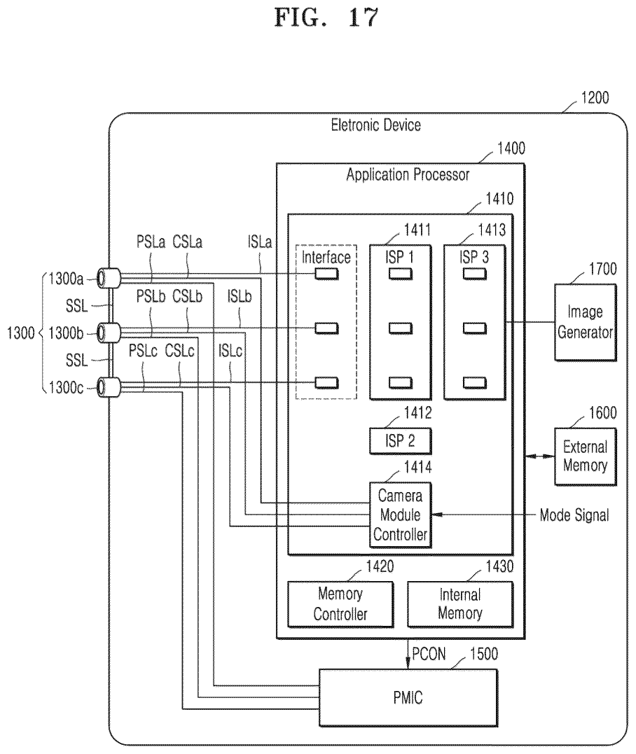

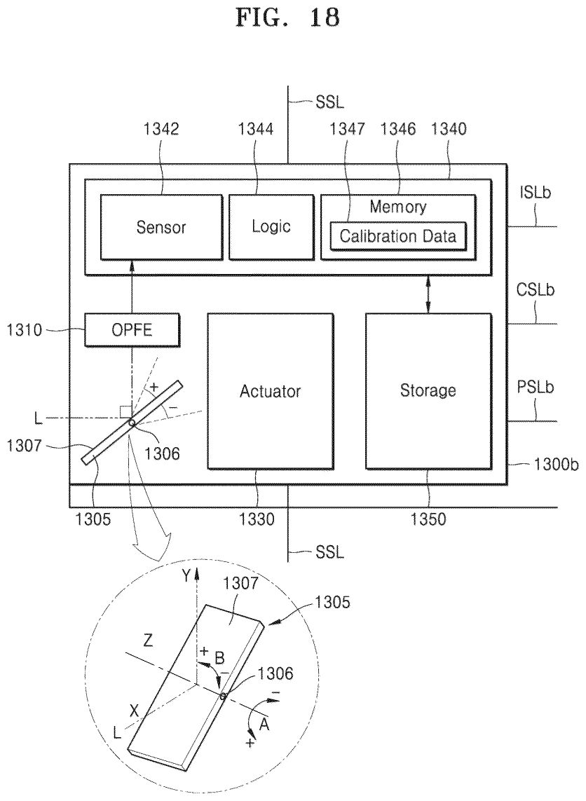

FIG. 17 is a block diagram of an electronic device including a multi-camera module, and FIG. 18 is a detailed block diagram of one camera module in the electronic device shown in FIG. 17.

Referring to FIG. 17, the electronic device 1200 may include a camera module group 1300, an application processor 1400, a power management integrated circuit (PMIC) 1500, an external memory 1600, and an image generator 1700.

The camera module group 1300 may include a plurality of camera modules 1300a, 1300b, and 1300c. Although the drawings show an example in which three camera modules 1300a, 1300b, and 1300c are arranged, embodiments are not limited thereto. In some embodiments, the camera module group 1300 may be modified to include only two camera modules. Also, in some embodiments, the camera module group 1300 may be modified to include n (n is 4 or greater natural number) camera modules.

Hereinafter, a detailed configuration of the camera module 1300b will be described in detail below with reference to FIG. 18, but the description provided below may be also applied to the other camera modules 1300a and 1300c according to the example embodiment.

Referring to FIG. 18, the camera module 1300b may include a prism 1305, an optical path folding element (OPFE) 1310, an actuator 1330, an image sensing device 1340, and a storage 1350.

The prism 1305 may include a reflecting surface 1307 of a light-reflecting material and may deform a path of light L incident from outside.

In some embodiments, the prism 1305 may change the path of the light L incident in the first direction (X-direction) into a second direction (Y-direction) that is perpendicular to the first direction (X-direction). Also, the prism 1305 may rotate the reflecting surface 1307 having the light-reflecting material about a center axis 1106 in a direction A, or about the center axis 1306 in a direction B so that the path of the light L incident in the first direction (X-direction) may be changed to the second direction (Y-direction) perpendicular to the first direction (X-direction). Here, the OPFE 1310 may also move in the third direction (Z-direction) that is perpendicular to the first direction (X-direction) and the second direction (Y-direction).

In some embodiments, as shown in the drawings, the maximum rotation angle of the prism 1305 in the direction A is 15° or less in the positive A direction and is greater than 15° in the negative A direction, but embodiments are not limited thereto.

In some embodiments, the prism 1305 may be moved by the angle of about 20°, or between 10° to 20° or 15° to 20° in the positive or negative B direction. Here, the moving angle is the same in the positive or negative B direction, or may be similar within a range of about 1°.

In some embodiments, the prism 1305 may move the reflecting surface 1307 of the light-reflective material in the third direction (e.g., Z direction) that is parallel to the direction in which the center axis 1306 extends.

The OPFE 1310 may include, for example, optical lenses formed as m groups (here, m is a natural number). Here, m lenses may move in the second direction (Y-direction) and thus may change an optical zoom ratio of the camera module 1300b. For example, when a basic optical zoom ratio of the camera module 1300b is Z and m optical lenses included in the OPFE 1310 move, the optical zoom ratio of the camera module 1300b may be changed to 3Z, 5Z, or 10Z or greater.

The actuator 1330 may move the OPFE 1310 or the optical lens (hereinafter, referred to as optical lens) to a certain position. For example, the actuator 1330 may adjust the position of the optical lens so that the image sensor 1342 may be located at a focal length of the optical lens for exact sensing operation.

An image sensing device 1340 may include the image sensor 1342, a control logic 1344, and a memory 1346. The image sensor 1342 may sense an image of a sensing target by using the light L provided through the optical lens. The control logic 1344 may control the overall operation of the camera module 1300b. For example, the control logic 1344 may control the operations of the camera module 1300b according to a control signal provided through a control signal line CSLb.

For example, the image sensor 1342 may include the image array 1100 including the color separating lens array 130 described above. The image sensor 1342 may further greatly receive signals separated according to wavelengths in each pixel by using the color separating lens array 130 based on the nanostructures. Due to this effect, an amount of light required to create high quality images at high resolution and low illuminance may be secured.

The memory 1346 may store information that is necessary for the operation of the camera module 1300b, e.g., calibration data 1347. The calibration data 1347 may include information that is necessary to create image data by using the light L provided from outside through the camera module 1300b. The calibration data 1347 may include, for example, information about the degree of rotation described above, information about the focal length, information about an optical axis, etc. When the camera module 1300b is implemented in the form of a multi-state camera of which the focal length is changed according to the position of the optical lens, the calibration data 1347 may include information related to focal length values of the optical lens according to each position (or each state) and auto-focusing.

The storage 1350 may store image data sensed through the image sensor 1342. The storage 1350 may be disposed out of the image sensing device 1340 or may be implemented in a stacked form with a sensor chip constituting the image sensing device 1340. In some embodiments, the storage 1350 may be implemented as electrically erasable programmable read-only memory (EEPROM), but one or more embodiments are not limited thereto.

Referring to FIGS. 17 and 18 together, in some embodiments, each of the plurality of camera modules 1300a, 1300b, and 1300c may include the actuator 1330. Accordingly, each of the plurality of camera modules 1300a, 1300b, and 1300c may include the calibration data 1347 that is the same as or different from the others, according to the operation of the actuator 1330 included therein.

In some embodiments, one (for example, 1300b) of the plurality of camera modules 1300a, 1300b, and 1300c may be a camera module in a folded lens type including the prism 1305 and the OPFE 1310 described above, and the other camera modules (for example, 1300a and 1300c) may be vertical type camera modules not including the prism 1305 and the OPFE 1310. However, embodiments are not limited thereto.

In some embodiments, one (for example, 1300c) of the plurality of camera modules 1300a, 1300b, and 1300c may be a depth camera of a vertical type, which extracts depth information by using infrared ray (IR).

In some embodiments, at least two camera modules (e.g., 1300a and 1300b) from among the plurality of camera module 1300a, 1300b, and 1300c may have different field of view (different viewing angle). In this case, for example, the optical lenses of the at least two camera modules (e.g., 1300a and 1300b) from among the plurality of camera modules 1300a, 1300b, and 1300c may be different from each other, but embodiments not limited thereto.

Also, in some embodiments, the plurality of camera modules 1300a, 1300b, and 1300c may have different field of view from one another. In this case, the optical lenses respectively included in the plurality of camera modules 1300a, 1300b, and 1300c may be different from one another, but embodiments not limited thereto.

In some embodiments, each of the plurality of camera modules 1300a, 1300b, and 1300c may be arranged to be physically separated from one another. For example, rather than dividing the sensing region of one image sensor 1342 to be used by the plurality of camera modules 1300a, 1300b, and 1300c, an independent image sensor 1342 may be disposed inside each of the plurality of camera modules 1300a, 1300b, and 1300c.

Referring back to FIG. 17, the application processor 1400 may include an image processing device 1410, a memory controller 1420, and an internal memory 1430. The application processor 1400 may be separately implemented from the plurality of camera modules 1300a, 1300b, and 1300c. For example, the application processor 1400 and the plurality of camera modules 1300a, 1300b, and 1300c may be separately implemented as separate semiconductor chips.

The image processing device 1410 may include a plurality of image processors 1411, 1412, and 1413, and a camera module controller 1414.

The image data generated by each of the camera modules 1300a, 1300b, and 1300c may be provided to the image processing device 1410 via separate image signal lines, respectively. The image data transfer may be carried out by using a camera serial interface (CSI) based on a mobile industry processor interface (MIPI), for example, but is not limited thereto.

The image data transferred to the image processing device 1410 may be stored in an external memory 1600 before being transferred to the image processors 1411 and 1412. The image data stored in the external memory 1600 may be provided to the image processor 1411 and/or the image processor 1412. The image processor 1411 may correct received image data in order to generate video. The image processor 1412 may correct received image data in order to generate still images. For example, the image processors 1411 and 1412 may perform a pre-processing operation such as a color calibration, a gamma calibration on the image data.

The image processor 1411 may include sub-processors. When the number of sub-processors is equal to the number of camera modules 1300a, 1300b, and 1300c, each of the sub-processors may process the image data provided from one camera module. When the number of sub-processors is less than the number of camera modules 1300a, 1300b, and 1300c, at least one of the sub-processors may process the image data provided from a plurality of camera module by using a timing-sharing process. The image data processed by the image processor 1411 and/or the image processor 1412 may be stored in the external memory 1600 before being transferred to the image processor 1413. The image data stored in the external memory 1600 may be transferred to the image processor 1412. The image processor 1412 may perform a post-processing operation such as a noise correction, sharpening correction, etc. on the image data.

The image data processed in the image processor 1413 may be provided to the image generator 1700. The image generator 1700 may generate a final image by using the image data provided from the image processor 1413 according to image generating information or a mode signal.

In detail, the image generator 1700 may generate an output image by merging at least some of the image data generated from the camera modules 1300a, 1300b, and 1300c having different field of view, according to image generating information or the mode signal. Also, the image generator 1700 may generate an output image by selecting one of pieces of image data generated by the camera modules 1300a, 1300b, and 1300c having different field of view, according to image generating information or the mode signal.

In some embodiments, the image generating information may include a zoom signal or a zoom factor. Also, in some embodiments, the mode signal may be, for example, a signal based on a mode selected by a user.

When the image generating information is a zoom signal (zoom factor) and the camera modules 1300a, 1300b, and 1300c have different field of view (angle of view) from one another, the image generator 1700 may perform different operations according to the kind of zoom signal. For example, when the zoom signal is a first signal, the image data output from the camera module 1300a is merged with the image data output from the camera module 1300c, and then, the output image may be generated by using the merged image signal and the image data output from the camera module 1300b not used in the merge. When the zoom signal is a second signal that is different from the first signal, the image generator 1700 may generate the output image by selecting one piece of the image data output respectively from the camera modules 1300a, 1300b, and 1300c without performing of the image data merging. However, embodiments are not limited thereto, and the method of processing the image data may be modified as necessary.

The camera module controller 1414 may provide control signals to each of the camera modules 1300a, 1300b, and 1300c. The control signals generated by the camera module controller 1414 may be provided to corresponding camera modules 1300a, 1300b, and 1300c via control signal lines CSLa, CSLb, and CSLc separated from one another.

In some embodiments, the control signals provided to the plurality of camera modules 1300a, 1300b, and 1300c from the camera module controller 1414 may include mode information according to the mode signal. The plurality of camera modules 1300a, 1300b, and 1300c may operate in a first operation mode and a second operation mode in relation to the sensing speed, based on the mode information.

In the first operation mode, the plurality of camera modules 1300a, 1300b, and 1300c may generate the image signal at a first speed (for example, generating an image signal of a first frame rate), encode the image signal at a second speed that is faster than the first speed (for example, encoding an image signal of a second frame rate that is greater than the first frame rate), and transfers the encoded image signal to the application processor 1400. Here, the second speed may be 30 times or less than the first speed.

The application processor 1400 may store the received image signal, that is, the encoded mage signal, in the memory 1430 provided inside or the storage 1600 outside the application processor 1400, and then, reads and decodes the encoded signal from the memory 1430 or the storage 1600, and may display the image data generated based on the decoded image signal. For example, the image processors 1411 and 1412 in the image processing device 1410 may perform decoding, and also may perform image processing on the decoded image signals.

In the second operation mode, the plurality of camera modules 1300a, 1300b, and 1300c generates an image signal at a third speed that is slower than the first speed (for example, generating the image signal of a third frame rate that is lower than the first frame rate), and may transfer the image signal to the application processor 1400. The image signal provided to the application processor 1400 may be a signal that is not encoded. The application processor 1400 may perform image processing on the received image signal or store the image signal in the memory 1430 or the storage 1600.

The PMIC 1500 may supply power, for example, source voltage, to each of the plurality of camera modules 1300a, 1300b, and 1300c. For example, the PMIC 1500 may supply first power to the camera module 1300a via a power signal line PSLa, second power to the camera module 1300b via a power signal line PSLb, and third power to the camera module 1300c via a power signal line PSLc, under control of the application processor 1400.

The PMIC 1500 may generate the power corresponding to each of the plurality of camera modules 1300a, 1300b, and 1300c and also may adjust the power level, in response to a power control signal PCON from the application processor 1400. The power control signal PCON may include a power adjusting signal for each operation mode of the plurality of camera modules 1300a, 1300b, and 1300c. For example, the operation mode may include a low power mode, and the power control signal PCON may include information about the camera module operating in the low-power mode and set power level. The levels of the power provided to the plurality of camera modules 1300a, 1300b, and 1300c may be equal to or different from one another. Also, the power level may be dynamically changed.

According to an image sensor and a method of manufacturing the image sensor according to an example embodiment, light utilization efficiency may be improved by separating and concentrating incident light by wavelength without absorbing or blocking the incident light, and nanostructures of various sizes may be implemented in accordance with the design to ensure optical performance.

It should be understood that embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing an image sensor, the method comprising:
forming a spacer layer on a sensor substrate that comprises a first pixel configured to sense light of a first wavelength and a second pixel configured to sense light of a second wavelength;
forming a dielectric layer on the spacer layer;
forming an engraved pattern in the dielectric layer through patterning; and
forming nanoposts included in a color separating lens layer by filling the engraved pattern formed in the dielectric layer with a nanostructure material,
wherein the forming of the engraved pattern in the dielectric layer comprises:
forming a first engraved pattern to form a plurality of first nanoposts that comprises a nanopost having a width that is less than or equal to an exposure diffraction limit, the plurality of first nanoposts having at least one or more widths; and
forming a second engraved pattern to form a plurality of second nanoposts that comprises a nanopost having a width that is greater than the exposure diffraction limit,
wherein the forming of the first engraved pattern comprises:
forming a first mask layer on the dielectric layer;
forming a first opening at a position where the first engraved pattern is to be formed by patterning the first mask layer through the patterning including an exposure process;
forming a sidewall within the first opening by forming a step cover layer on the patterned first mask layer;
etching the dielectric layer through the first opening;
forming the first engraved pattern having a width less than a width of the first opening by a sidewall portion of the step cover layer left during an etching process; and
removing the first mask layer.

2. The method of claim 1, wherein the forming of the second engraved pattern comprises:
forming a second mask layer on the dielectric layer;
forming a second opening at a position where the second engraved pattern is to be formed by patterning the second mask layer;
forming the second engraved pattern having a width corresponding to the second opening by etching the dielectric layer through the second opening; and
removing the second mask layer.

3. The method of claim 2, wherein the plurality of first nanoposts are formed by forming of the first engraved pattern, and filling the first engraved pattern with the nanostructure material, and
wherein the plurality of second nanoposts are formed by forming of the second engraved pattern, and filling the second engraved pattern with the nanostructure material.

4. The method of claim 3, wherein the filling of the nanostructure material to form the plurality of first nanoposts is performed after the removing of the first mask layer, and
wherein the filling of the nanostructure material to form the plurality of second nanoposts is performed after the removing of the second mask layer.

5. The method of claim 3, wherein the plurality of first nanoposts and the plurality of second nanoposts are formed respectively by filling the first engraved pattern and the second engraved pattern with the nanostructure material simultaneously.

6. The method of claim 1, wherein the step cover layer is removed during the etching to form the first engraved pattern.

7. The method of claim 1, wherein a refractive index of the nanostructure material is greater than a refractive index of the dielectric layer.

8. The method of claim 1, further comprising:
forming an etch stop layer on the spacer layer,
wherein the dielectric layer is formed on the etch stop layer.

9. The method of claim 1, further comprising:
forming a second etch stop layer on the color separating lens layer; and
forming a second color separating lens layer on the color separating lens layer.

10. The method of claim 9, wherein the second color separating lens layer is formed simultaneously as forming of the color separating lens layer after the forming of a spacer layer on the sensor substrate.

11. An image sensor comprising:
a sensor substrate comprising a two-dimensional (2D) array of unit pixels that respectively comprise a first pixel configured to sense light of a first wavelength and a second pixel configured to sense light of a second wavelength;
a transparent spacer layer on the sensor substrate; and
a color separating lens layer on the spacer layer,
wherein the color separating lens layer, in a region corresponding to at least one pixel of the unit pixels, comprises: first nanoposts comprising a nanopost having a width that is less than or equal to an exposure diffraction limit, the first nanoposts having at least one or more widths; and
second nanoposts comprising a nanopost having a width greater than the exposure diffraction limit.

12. The image sensor of claim 11, further comprising:
a second color separating lens layer on the color separating lens layer,
wherein the second color separating lens layer, in a region corresponding to at least one pixel of the unit pixels, comprises:
third nanoposts comprising a nanopost having a width that is less than or equal to the exposure diffraction limit, the third nanoposts having at least one or more widths; and
fourth nanoposts comprising a nanopost having a width greater than the exposure diffraction limit.

13. The image sensor of claim 11, wherein the sensor substrate comprises a first green pixel, a blue pixel, a red pixel, and a second green pixel in a Bayer pattern arrangement,
wherein, when width sizes of the second nanoposts in a first green pixel corresponding region and a second green pixel corresponding region corresponding to the first green pixel and the second green pixel, a blue pixel corresponding region corresponding to the blue pixel, and a red pixel corresponding region corresponding to the red pixel of the color separating lens layer are Pa, Pb, and Pc, respectively, the width sizes of the second nanoposts in the first green pixel corresponding region and the second green pixel corresponding region, the blue pixel corresponding region, and the red pixel corresponding region are in an order of Pb>Pc>Pa.

14. The image sensor of claim 13, wherein one second nanopost is in the blue pixel corresponding region,
wherein four second nanoposts are symmetrically at positions spaced apart from a center in the red pixel corresponding region, and
wherein four second nanoposts are at positions spaced apart from the center and symmetrically in the first green pixel corresponding region and the second green pixel corresponding region.

15. The image sensor of claim 14, wherein a width of at least one of first nanoposts in the blue pixel corresponding region is less than a width of each of first nanoposts in the first green pixel corresponding region, the second green pixel corresponding region, and the red pixel corresponding region.

16. An electronic device comprising:
an image sensor configured to convert an optical image into an electrical signal; and
a processor configured to control an operation of the image sensor and store and output the electrical signal generated by the image sensor,
wherein the image sensor comprises:
a sensor substrate having a two-dimensional (2D) array of unit pixels respectively comprising a first pixel configured to sense light of a first wavelength and a second pixel configured to sense light of a second wavelength;
a transparent spacer layer on the sensor substrate; and
a color separating lens layer on the spacer layer,
wherein the color separating lens layer, in a region corresponding to at least one pixel of the unit pixels, comprises:
first nanoposts comprising a nanopost having a width that is less than or equal to an exposure diffraction limit, the first nanoposts having at least one or more widths; and
second nanoposts comprising a nanopost having a width greater than the exposure diffraction limit.

17. The electronic device of claim 16, wherein the image sensor further comprises:
a second color separating lens layer on the color separating lens layer,
wherein the second color separating lens layer, in a region corresponding to at least one pixel of the unit pixels, comprises:
third nanoposts comprising a nanopost having a width that is less than or equal to the exposure diffraction limit, the third nanoposts having at least one or more widths; and
fourth nanoposts comprising a nanopost having a width greater than the exposure diffraction limit.

18. The electronic device of claim 16, wherein the sensor substrate comprises a first green pixel, a blue pixel, a red pixel, and a second green pixel in a Bayer pattern arrangement, and
wherein when width sizes of the second nanoposts in a first green pixel corresponding region and a second green pixel corresponding region corresponding to the first green pixel and the second green pixel, a blue pixel corresponding region corresponding to the blue pixel, and a red pixel corresponding region corresponding to the red pixel of the color separating lens layer are Pa, Pb, and Pc, respectively, the width sizes of the second nanoposts in the first green pixel corresponding region and the second green pixel corresponding region, the blue pixel corresponding region, and the red pixel corresponding region are in an order of Pb>Pc>Pa.

19. The electronic device of claim 18, wherein one second nanopost is in the blue pixel corresponding region,
wherein four second nanoposts are symmetrically at positions spaced apart from a center in the red pixel corresponding region, and
wherein four second nanoposts are disposed at positions spaced apart from the center and symmetrically in the first green pixel corresponding region and the second green pixel corresponding region.

20. The electronic device of claim 19, wherein a width of at least one of first nanoposts in the blue pixel corresponding region is less than a width of each of first nanoposts in the first green pixel corresponding region, the second green pixel corresponding region, and the red pixel corresponding region.
